(19) United States
(12) Patent Application Publication
(10) Pub. No.: US 2026/0053023 A1
(43) Pub. Date: Feb. 19, 2026

(54) FOLDED HIGH-BANDWIDTH MEMORY SYSTEMS

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/896,770

(22) Filed: Sep. 25, 2024

Related U.S. Application Data
(60) Provisional application No. 63/684,280, filed on Aug. 16, 2024.

(51) Int. Cl. H01L 23/498; H01L 23/00; H01L 25/18; H10B 80/00

(52) U.S. Cl. CPC H01L 23/49838; H01L 23/49827; H01L 24/08; H01L 24/89; H01L 25/18; H10B 80/00; H01L 2224/08112; H01L 2224/08167; H01L 2224/89; H01L 2924/15159

(57) ABSTRACT

Methods for fabricating flexible interposers for providing electrical connection between devices mounted at different vertical positions with respect to a substrate or a planar interposer. A bonded structure may comprise a bent flexible interposer extending from a first interposer portion between a main device on the substrate or the planar interposer and a second interposer portion above the main device and above or below a device positioned above the main device and electrically connected to the main device via a bent portion of the flexible interposer.

### INCORPORATION BY REFERENCE TO ANY PRIORITY APPLICATIONS

This application claims priority to U.S. Provisional Application No. 63/684280 filed on Aug. 16, 2024, titled “FOLDED HIGH-BANDWIDTH MEMORY SYSTEMS” that is hereby incorporated herein by reference in its entirety.

### BACKGROUND

### Field

The field relates to structures for providing electrical connection between an electronic chip and memory stacks. In particular, establishing electrical connections using interposers having flexible regions and hybrid bonding surfaces including dielectric and conductive regions and methods for forming the same.

### Description of the Related Art

Semiconductor elements, such as integrated device dies or chips, may be mounted or stacked on other elements. For example, a semiconductor element can be stacked on top of another semiconductor element and the bonded elements can electrically communicate with one another through contact pads included in the hybrid bonding surfaces. For example, hybrid bonding surfaces of a first and second integrated device dies can be bonded on to hybrid bonding surfaces of a semiconductor substrate and the first and second integrated device dies can electrically communicate via contact pads of the respective hybrid binding surfaces. It can be challenging to integrate semiconductor elements of different types or material sets, on a substrate or in a package due to, for example, mismatches in coefficient of thermal expansion (CTE). Further, it can be challenging to provide communication between stacks of semiconductor elements and to maintain a low profile for the package or device.

### SUMMARY

In some aspects, the techniques described herein relate to a bonded structure including: a processor chip disposed over a main surface of a first interposer; a first memory device disposed over the first interposer; and a second memory device disposed over the processor chip; wherein the first memory device is electrically connected to the processor chip via the first interposer; wherein the second memory device is electrically connected to the processor chip; and wherein electrical connections between the processor chip and the first and second devices include a data communication link.

In some aspects, the techniques described herein relate to a bonded structure including: a processor chip; a first memory device disposed over the processor chip; and a flexible interposer electrically connecting the processor chip to the first memory device; wherein the flexible interposer includes a first interposer portion electrically connected to the processor chip, a second interposer portion electrically connected to the first memory device, and a bent interposer portion electrically connecting the first and second interposer portions.

In some aspects, the techniques described herein relate to a method of fabricating a bonded structure, the method including: providing an interposer structure including a first interposer portion having a first plurality of contact pads, a second interposer portion having a second plurality of contact pads, and a flexible middle interposer portion extending between the first and second interposer portions, bonding a processor chip to the first interposer portion to electrically connect the processor chip to the first plurality of contact pads; bonding a memory device to the second interposer portion to electrically connect the second plurality of contact pads to contact pads one a bottom surface of the memory device; bending at least the flexible middle interposer portion to position the memory device above the processor chip and to align a top surface of the memory device, opposite to the bottom surface, to a top surface of the processor chip.

### BRIEF DESCRIPTION OF THE DRAWINGS

The detailed description is set forth with reference to the accompanying figures. The use of the same numbers in different figures indicates similar or identical items. For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A schematically illustrates an example flexible hybrid bonding structure including a flexible layer and a hybrid bonding surface with two separate regions for directly bonding two devices and providing an electrical connection between them.

FIG. 1B schematically illustrates a double-sided flexible hybrid bonding structure including a flexible layer and two hybrid bonding surfaces formed on opposite sides of the double-sided flexible hybrid bonding structure for direct bonding of two or more devices on opposite sides of the double-sided flexible hybrid bonding structure and providing an electrical connection between them.

FIG. 2A schematically illustrates a cross-sectional side view of an example bonded structure for providing electrical connection between an electronic processor chip and two memory devices using a planar interposer.

FIG. 2B schematically illustrates a cross-sectional side view of another example bonded structure for providing electrical connection between an electronic processor chip and two memory devices using an interconnect region embedded in a substrate.

FIG. 3A schematically illustrates a side cross-sectional view of a bonded structure comprising a bent flexible interposer electrically connecting an electronic processor chip to a memory device positioned above the electronic processor chip. The inset schematically illustrates the flexible interposer prior to being included in the bonded structure.

FIG. 3B schematically illustrates a side cross-sectional view of another bonded structure comprising a bent flexible interposer electrically connecting an electronic processor chip to a memory device positioned above the electronic processor chip and below the flexible interposer. The inset schematically illustrates the flexible interposer prior to being included in the bonded structure.

FIGS. 4A-4D schematically illustrate selected steps of an example process for fabricating the bonded structure shown in FIG. 3B.

FIGS. 5A-5D schematically illustrate selected steps of an example process for fabricating a bonded structure having a support layer.

FIG. 6A schematically illustrates side-cross sectional view of an extended bonded structure comprising a flexible interposer and a planar interposer electrically connecting an electronic processor chip mounted on the planar interposer to a first memory device above the electronic processor chip and a second memory device disposed on the planar interposer.

FIG. 6B schematically illustrates side-cross sectional view of an extended bonded structure comprising a flexible interposer and a planar interposer electrically connecting an electronic processor chip mounted on the planar interposer to two memory devices above the electronic processor chip and a third memory device disposed on the planar interposer. The inset schematically illustrates the flexible interposer prior to being included in the extended bonded structure.

FIG. 7 schematically illustrates side-cross sectional view of an extended bonded structure comprising a flexible interposer and a planar interposer electrically connecting an electronic processor chip mounted on the planar interposer to a memory device above on a cooling device (or component) disposed on the electronic processor chip and a second memory device disposed on the planar interposer.

FIGS. 8A-8B schematically illustrate cross-sectional side views of two hybrid bonding structures (8A) prior to hybrid bonding and (8B) after hybrid bonding.

### DETAILED DESCRIPTION

There is a growing demand for directly bonding semiconductor elements having contact pads arranged at a fine pitch, so as to increase interconnect density and provide improved electrical capabilities. Direct hybrid bonds may be formed by fabricating semiconductor elements (e.g., wafers, panels or dies) having polished bonding surfaces including a nonconductive field region and one or more conductive features (e.g., conductive contact pads) at least partially embedded in the nonconductive field region. The nonconductive field regions of two semiconductor elements can be directly (e.g., using hybrid bonding) bonded at low temperature without using an adhesive to form a bonded structure (e.g., via covalently bonded dielectric-to-dielectric surfaces). The directly bonded structure can be heated to cause expansion of the conductive contact pads therein so as to form a bond between opposing surfaces of the conductive contact pads and thereby provide electrical connection between the conductive contact pads effectively forming a hybrid bonded structure. Accordingly, a hybrid bonding surface comprises nonconductive (e.g., dielectric) and conductive regions formed on a nonconductive (e.g., insulating) layer. In some embodiments, the nonconductive region of the hybrid bonding surface may comprise an inorganic dielectric material. In some cases, the nonconductive (e.g., dielectric or field regions) may be activated for direct bonding. In the embodiments disclosed herein, a hybrid bonding interface (also referred to as hybrid bonded region) can include a boundary of two hybrid bonding surfaces providing electrical connection between at least two opposing contact pads. A hybrid bonding (or substrate) layer may comprise a layer (or substrate) having at least one hybrid bonding surface configured to be hybrid bonded to a hybrid bonding surface of another element (e.g., a component, die, structure, substrate, or the like). In some cases, a hybrid surface may comprise nonconductive (e.g., dielectric) and conductive regions where the nonconductive regions are not activated for direct bonding. In some examples, a dielectric region of a hybrid surface may be activated by adding suitable species (e.g., nitrogen species) to form a hybrid bonding surface.

In various implementations, a substrate (e.g., a hybrid bonding substrate, a planar interposer, a flexible interposer) may comprise an insulating material with embedded conductive traces and contact features. The substrate can be devoid of active circuitry and passive circuitry, such that the substrate's only function is to route signals along the conductors. But in other embodiments, the substrate can include embedded passive devices. The substrates illustrated herein are flexible substrates (e.g., they may comprise an organic layer), but in other embodiments, the substrate can comprise other types of substrates, such as a printed circuit board (PCB), a ceramic substrate, and the like.

In some cases, a portion of a hybrid bonding substrate or layer may be displaced with respect to another portion of the same substrate or layer, e.g., bent or folded by a mechanical force or due to thermal expansion. As an example, a first portion of a hybrid bonding substrate or layer may be used to provide electrical connection between a first component and a second component vertically displaced with respect to the first component. Various hybrid layers and substrates disclosed herein may include a flexible region, flexible portion, or flexible layer that allows two different portions or sections a hybrid layer or structure to be displaced by different amounts (e.g., bent or folded) without causing mechanical damage in the substrate or layer or electrical disconnection between different sections of the substrate or layer. In some embodiments, the flexible portion may comprise a thin portion having a thickness which allows the hybrid layer to have a desired radius of curvature without being mechanically damages and without loss of electrical connection between two sections between which the curved portion in formed. In various implementations, thickness of the curved portion can be smaller, equal, or larger than the two sections. In some embodiments, the flexible hybrid layer may comprise a thin layer of silicon dioxide, silicon, another dielectric, or another semiconductor.

For example, some of the disclosed methods may be used to fabricate a flexible hybrid bonding substrate comprising one or more contact pads and/or conductive lines partially embedded in a flexible (or deformable) layer having at least one hybrid bonding surface. In various implementations, a flexible layer may comprise compliant material comprising organic material such as a polymer, e.g., a liquid crystal polymer (LCP) and/or a polyimide (e.g. PYRALIN® PI 2611) or polyamide-imide (e.g., Torlon®) or silicone rubber or benzocyclobutene (BCB) for example. In some cases, a flexible layer may comprise one or more compliant materials. For a examples, a mixture or combination of different types of polymers. In some, cases, a flexible layer may comprise 5-10 weight %, 10-20 weight %, 20-40 weight %, 40-50 weight %, 50-60 weight %, 60-70 weight %, 70-80 weight %, 80-90 weight %, or 90-100 weight %, polymer or another compliant material. In some cases, a flexible layer or substrate, may comprise a deformable region or a deformable layer comprising a compliant material. In some cases, a complaint material may have a Young's modulus from 0.02 GPa to 0.5 GpA, from 0.2 to 1 GPa, from 1 GpA to 2 GPa, 0.05 GPa to 2 GPa, 5 GPa to 10 GPa, 10 to 45 GPa, 45 to 50 GPa or any ranges formed by these values or larger or smaller values. In some embodiments, the compliant material selected to have a Young's modulus that allows the corresponding flexible substrate (having a deformable region comprising the compliant material) to be deformed more than or equal to a minimum desired deformation. In some examples, a desired deformation may comprise a radius of curvature of a bent flexible substrate to be less than 100 times, less than 50 times, or less than 20 times the thickness of the flexible substrate without disrupting an electrical connection within the substrate. As such, in some cases, the compliant material selected based at least in part on a thickness of the substrate (e.g., along a direction normal to a main surface of the substrate). For example, when a thickness of the deformable region, along a direction normal to a main surface of the substrate, is larger than 5 microns, the compliant material (the deformable region of the substrate) may be selected to have Young's modulus less than 40 GPa.

In some embodiments, the deformable region can be configured to allow a first region of the second hybrid bonding surface to be displaced with respect to a second region of the first hybrid bonding surface (of the main portion) by an amount larger than 5% of a distance between the first and the second regions without disrupting an electrical connection between the conductive portions of the first and second regions. In some cases, the first region may comprise a first hybrid bonding interface and the second region may comprise a second hybrid bonding interface. In some such cases, the first and/or the second hybrid bonding interfaces may comprise hybrid bonding interface between an interposer and one or more components (e.g., dies, semiconductor components, and the like).

In some examples, a flexible hybrid layer or substrate may be configured to allow two hybrid surface regions spaced apart by a distance equal to the thickness of the layer or substrate, to be displaced with respect to each other by more than the 20%, 50%, 100%, 200%, 300%, 400%, 500% of the thickness without suffering mechanical damage, and/or disrupting electrical connectivity (e.g., between the two hybrid surface regions (e.g., due to disconnection of an electrical link at least partially embedded in the layer or substrate). In some examples, a flexible layer or a compliant portion of a flexible layer (e.g., a polymer layer) may have a coefficient of thermal expansion (CTE) greater than 1 ppm/° C. and less than 60 ppm/° C. In some examples, a flexible layer or a compliant portion of a flexible layer (e.g., a polymer layer) may have a CTE from 0.5 ppm/° C. to 1 ppm/° C., from 1 ppm/° C. to 2 ppm/° C., from 2 ppm/° C. to 5 ppm/° C., from 5 ppm/° C. to 15 ppm/° C., from 15 to 20 ppm/° C., from 20 to 30 ppm/° C., from 30-40 ppm/° C., from 40 to 50 ppm/° C., from 50 to 60 ppm/° C. or any ranges formed by these values or larger or smaller. In some examples, a flexible layer or substrate may comprise a composite material. In some such examples, the composite material can be an inorganic material, an organic material, or a combination thereof. In some such examples, the composite material may comprise particulate reinforcement in the form or fibers (e.g., chopped fibers), particles, or particles having any shapes. In some cases, the particulate reinforcement can be less than 10%, 20%, or 30% of the volume of the material. In some cases, the composite material may include less than 10, 20, or 30 weight % of the reinforcing particulates. In some cases, particulate reinforcement may comprise inorganic or organic particles or fibers, for example a polyimide or silicone polymer containing milled para-aramid (Kelvar®) reinforcing particulates. In some embodiments, a flexible layer may comprise a flexible region that allows two regions or sections of the flexible layer on the opposite sides of the flexible region to be displaced relative to each other by an amount larger than X % of the thickness of the flexible layer without being damaged and/or without disrupting an electrical connection via the flexible region. In some cases, X can be larger than 20%, larger than 70%, larger than 90%, larger than 100%, larger than 150% or larger values. In some cases, such flexible region may comprise one or more conductive lines electrically connecting conductive portion of the two regions or sections. In some cases, the relative displacement between the two regions or sections can be along a direction parallel to a main surface of the flexible layer, or perpendicular to a main surface of the flexible layer.

In some embodiments, a sublayer, a layer, or region of a substrate or structure may be considered to be flexible even though the layer or structure is rendered inflexible due to presence of other layers or a surrounding material, such as a molding compound.

### Examples of Direct Bonding Methods and Hybrid Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to plasma, explained below).

The hybrid bonding interface (also referred to as hybrid bonded region) between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the hybrid bonding interface between non-conductive bonding surfaces. In some embodiments, the hybrid bonding interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

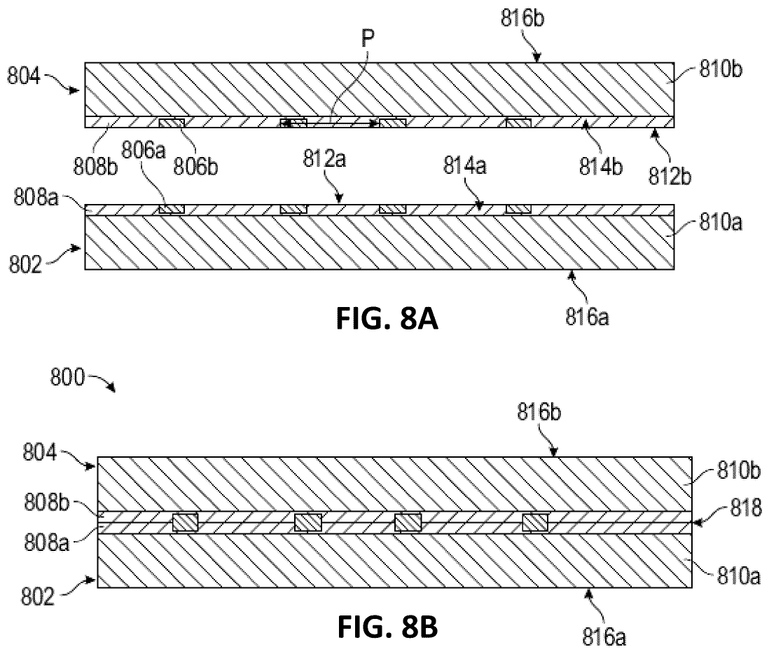

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a hybrid bonding interface (or hybrid bonded region) 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814b, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers (conductive layer damascene process or non-damascene coating of conductive layer) during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814b, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 1700 ppm/° C., 5 ppm/° C. to 40 ppm/° C., 10 ppm/° C. to 1700 ppm/° C., or 10 ppm/° C. to 40 ppm/° C. or any ranges formed by these values or larger or smaller.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent to one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a hybrid bonding interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the hybrid bonding interface (or hybrid bonded region) 818 between two non-conductive materials (e.g., the bonding layers 808a, 808b) can comprise a very smooth interface with higher nitrogen (or other terminating species) content and/or fluorine concentration peaks at the hybrid bonding interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be hybrid bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct hybrid bonding interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the hybrid bonding interface 818. In some embodiments, the metal is or includes copper, which can have grains oriented along the 111 crystal plane for improved copper diffusion across the hybrid bonding interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

As described above, in some embodiments, two elements (e.g., two layers, a layer and a die, a layer and a substrate, a die and a substrate, or other combinations) can be hybrid bonded to one another without an adhesive, e.g., by low temperature dielectric-to-dielectric bonding. In some cases, each element may include a non-conductive (e.g., dielectric) field region comprising at least one non-conductive material (dielectric material). In some examples, the non-conductive material (also referred to as a dielectric bonding material) can be an inorganic dielectric. In some examples, a non-conductive field region of an element is a dielectric layer (e.g., an inorganic dielectric layer). A dielectric layer of the first element can be directly bonded to a corresponding dielectric layer of the second element without an adhesive. In some embodiments, the dielectric layer of at least one element may be disposed on a flexible region or flexible layer of the element. In some cases, the flexible region or flexible layer can be deformable region of layer configured to be deformed without a damage to its morphology or a disruption in electrical connectivity therein. In some embodiments, the flexible region may be an elastically deformable material. A region of a dielectric layer that is bonded to the corresponding region of another dielectric layer can be referred to as nonconductive bonding region, dielectric bonding region, or bonding region. In some cases, the bonding region of the dielectric layer may comprise a dielectric bonding surface region. The dielectric bonding surface of a dielectric layer may be also referred to as a field area or a field region of the dielectric layer. In some cases, the nonconductive bonding region or dielectric bonding region and the top conductive surfaces of contact pads therein may be collectively referred to as hybrid bonding surface region of a substrate, a layer, or an element.

In some embodiments, the nonconductive material of the first element can be directly bonded to the corresponding nonconductive material of the second element using dielectric-to-dielectric bonding techniques (e.g., low temperature covalent bonding). In some cases, a first bonding region may have a first bonding surface and a second bonding region may have a second bonding surface. For example, dielectric-to-dielectric bonds may be formed between the first bonding surface of the first element and the second bonding surface of the second element without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In some examples, the bonding surface of the dielectric bonding regions can be polished to a high degree of smoothness (e.g., to improve a dielectric-to-dielectric bond). The bonding surfaces can be cleaned and exposed to a plasma and/or etchants to activate the surfaces. The activation process may enable or facilitate direct dielectric-to-dielectric bonding process. In some embodiments, the activated bonding surfaces or the field area can be terminated with suitable species, such as a nitrogen species.

Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes. In various embodiments, the bonding surface prepared by the procedure described above may enable forming a bond between the first and the second element without an intervening adhesive.

In some embodiments, a dielectric layer may include one or more conductive contact pads. A conductive contact pad (also referred to as “contact pad”) comprises a conductive material (e.g., copper, nickel, gold, or a metal alloy) and may be embedded in the dielectric layer. In some examples, a conductive contact pad may comprise a conductive bonding surface (e.g., a polished conductive surface) that can form a bond with the conductive bonding surface of another conductive contact pad without an adhesive. The bond formed between two contact pads (e.g., via their conductive bonding surfaces), can be an electrically conductive bond. In some embodiments, the contact pads or features of the bonding surface of the first substrate or element may comprise a material different from a material used to form the contact pads or features of the bonding surface of the second substrate or element.

In some cases, a surface that comprises the bonding surface (dielectric bonding surface) of the dielectric layer and the conductive bonding surface of the conductive contact pad, may be referred to as a hybrid bonding surface. In various embodiments, two hybrid bonding surfaces may form hybrid direct bonds between the first and the second elements without an intervening adhesive. The hybrid direct bond may formed such that a first dielectric bonding surface of the first element is bonded to a second dielectric bonding surface of second element, and a first conductive bonding surface of the first element is bonded to a second conductive bonding surface of the second element to electrically connect a first contact pad of the first element to a second contact pad of the second element. In some cases, after direct bonding, a hybrid bonding interface between a first hybrid bonding surface of the first element and a second hybrid bonding surface of the second element. A hybrid direct bond or hybrid bond may comprise at least one conductive region or contact pad in addition to the dielectric bonding region. In some embodiments, each element may include one or more conductive contact pads. In these embodiments, the conductive contact pads of the first element can be directly bonded to corresponding conductive contact pads of the second element. For example, a hybrid bonding technique can be used to provide conductor-to-conductor direct bonds along a bond interface formed between two conductive bonding surfaces and between covalently direct bonded dielectric-to-dielectric surfaces, prepared as described above. In various embodiments, the conductor-to-conductor (e.g., contact pad to contact pad) direct bonds and the dielectric-to-dielectric direct bonds can be formed using the direct bonding techniques disclosed at least in U.S. Pat. Nos. 9,716,033 and 9,852,988, the entire contents of each of which are incorporated by reference herein in their entirety and for all purposes. Conductive contact pads (which may be surrounded by nonconductive dielectric field regions) may also directly bond to one another without an intervening adhesive.

In some embodiments, the respective contact pads can be recessed below bonding surfaces of the dielectric layer. In some examples, the conductive bonding surface of the contact pads of a dielectric layer can be recessed by less than 30 nm, less than 20 nm, less than 15 nm, or less than 10 nm, for example, or recessed in a range of 2 nm to 20 nm, or in a range of 4 nm to 10 nm, with respect to a bonding surface of the dielectric layer. In some examples, the conductive bonding surface of a contact pad can be recessed below the bonding surface by less than 5 Å, 10 Å, 20 Å, or 100 Å.

In some embodiments, the dielectric bonding regions are directly bonded to one another without an adhesive at room temperature and, subsequently, the bonded structure is annealed at an elevated temperature (e.g., above room temperature). Upon annealing, the contact pads can expand and contact one another to form a metal-to-metal direct bond. In some embodiments, the directly bonded opposing contact pads or traces may comprise different types of metals. In some such embodiments, the annealing process may result in formation of bonded pads comprising a metallic alloy.

In some embodiments, the pitch of the contact pads, or conductive traces embedded in the bonding surface of one of the bonded elements, may be less than 40 microns, or less than 10 microns or even less than 1 microns. For some applications, the ratio of the pitch of the contact pads to one of the dimensions of the contact pad (e.g., the width or the length of the contact pad) can be less than 5, or less than 3 and sometimes desirably less than 2. In other applications, the width of a contact pad (e.g., a longitudinal distance between two ends for the contact pad) embedded in the bonding surface of one of the bonded elements may range between 0.3 to 30 microns. In various embodiments, the contact pads and/or traces can comprise copper or silver, gold, tin, nickel, carbon or an alloy comprising these materials although other conductive materials may be suitable.

Thus, in direct hybrid bonding processes (herein referred to as direct bonding), the dielectric bonding regions and the contact pads of a first element can be directly bonded to those of a second element without an intervening adhesive and form a bonded structure. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

Various embodiments disclosed herein relate to hybrid bonded structures in which at least two elements are hybrid bonded to one another without an intervening adhesive. Such hybrid bonded structures, which can comprise direct hybrid bonds, may be referred to as Direct Bond Interconnects (DBI®). In particular, hybrid bonded structures having one or more conductive interconnects (or vias) formed by direct bonding of conductive contact pads and at least one flexible region or layer are described.

In some embodiments, at least one element may comprise a flexible region or a flexible layer, a hybrid bonding surface, and one or more conductive contact pads (herein referred to as contact pads). In some examples, a flexible substrate or a flexible layer may comprise a flexible or deformable material. In some examples, a flexible substrate or a flexible layer may be a flexible region comprising a deformable material. In some examples, a flexible substrate or a flexible layer may be composed of a flexible or deformable material (e.g., an organic material).

In some embodiments, a first hybrid bonding surface can be formed on a flexible layer or a flexible substrate. In some such embodiments, the flexible region or section of the flexible substrate or layer may comprise at least a portion of the hybrid bonding surface and at least one of the contact pads. In some cases, the one or more contact pads can be electrically connected to conductive traces and/or vias that are at least partially embedded in a flexible region of a flexible substrate or layer.

In some embodiments, another layer or a die (e.g., a component such as an electronic component) comprising a second hybrid bonding surface and at least one second contact pad may be directly bonded to the first hybrid bonding surface of the flexible layer or substrate. The die may comprise an integrated electronic device (e.g., a semiconductor electronic device). In some cases, the die may be hybrid bonded on the flexible layer or substrate to electrically connect the die to another die hybrid bonded to the flexible substrate or layer (e.g., to an inorganic layer on the flexible layer(s)), or to another layer or substrate. Advantageously, the flexible portion of the flexible substrate (or layer) may provide a mechanically flexible electrical connection between the two dies, two layers, two substrates, a die and a substrate, and the like, allowing them to move with respect to each other (e.g., due to thermal expansion) while being electrically connected.

In some cases, the other element can be a second substrate (e.g., a second flexible substrate) comprising a hybrid bonding surface and a second contact pad. The second substrate may further comprise conductive traces and vias configured to electrically connect the second contact pad and one or more other contact pads of the second substrate. In some embodiments, the second substrate may comprise a flexible region or layer. In some examples, the second substrate may be composed of a flexible (or deformable) material.

As mentioned above a flexible layer, substrate, or region may comprise a flexible, deformable, or otherwise compliant material. In some embodiments the deformable material can be an organic material comprising a polymer (e.g., liquid crystal polymer and/or a polyimide). In some cases, the deformable material can be transparent in the visible and infra red light. For examples, a flexible layer may have an optical transmission larger than 30%, 40%, 50%, 60%, 70%, 80%, or larger values in a wavelength range from 450 nm to 1200 nm, from 500 nm to 1000, or from 400 nm to 800 nm.

In some embodiments, two or more substrates may be stacked on or bonded (e.g., hybrid bonded) to one another to form a bonded structure and allow electrical contact between one or more conductive lines in a first element (e.g., a first die) and one or more conductive lines in a second element (e.g., a second die). In some embodiments, two or more substrates may be stacked on or bonded (e.g., hybrid bonded) to one another to form a bonded structure and allow electrical or optical pathway or both between a first element (e.g., a first die) and a second element (e.g., a second die). Conductive contact pads of the first element may be electrically connected to corresponding conductive contact pads of the second element via the contact pads and conductive lines of the intervening substrates. Any suitable number of elements (e.g., layers) can be stacked to form a multilayer bonded structure. Any number of layers or substrates can be stacked (e.g., daisy-chained together) to form a layered structure of any suitable thickness or dimension. In some embodiments, at least one of the layers in the stack of layers may comprise a flexible region (or layer) or a core layer composed of a flexible (deformable) material.

Advantageously, a flexible substrate or layer, may reduce a mechanical coupling between the first element and the second element such that a change in the dimensions, or position of the first element or a change of strain in a region of the first element (e.g., due to temperature changes or a mechanical force) of the first element is different from the resulting change in the dimensions, or position of the second element or the resulting change of strain in a region of the second element. In some embodiments, the radius of curvature of a bent flexible substrate can be less than 100 times the thickness of a thickness of the substrate, less than 50 times a thickness of the substrate and even less than 20 times a thickness of the substrate. Moreover, the use of flexible substrate(s) can beneficially improve the utility of integrated devices and packages. For example, the flexible substrate(s) can be bent or deformed when subject to relatively small forces (e.g., forces imposed by typical human, manual, or robotic exertion) so as to enable the positioning of the substrate(s) (and therefore the devices mounted thereto) at arbitrary orientations and configurations.

A substrate or layer that includes a flexible region or layer, a contact pad, and a hybrid bonding surface may be referred to as a flexible hybrid bonding substrate or layer. In other words, a flexible hybrid bonding substrate is a flexible substrate having a hybrid bonding layer. A structure or stack (e.g., a structure or stack described above) that comprises at least one element having a flexible region or layer, hybrid bonded to another element, which may or may not include a flexible region or layer, may be referred to as a flexible bonded structure. For example, one or more dies hybrid bonded to a flexible hybrid bonding substrate may form a flexible bonded structure.

In some cases, a flexible layer or substrates (e.g., a hybrid flexible layer or substrate) may be included in a structure, device, part, or component used in an application where at least a portion of the structure, device, part, or component can move, be stretched, bent, or otherwise deformed during at least a portion of an operational period. Nonlimiting examples of such devices or components may include sensors on a wristband or ring configured for heart rate monitoring (or other health related monitoring), signal emitters arranged on wearable structures to emit signal locations for tracking the wearer's movements, or the like.

The flexible hybrid bonding substrates and layers and the corresponding flexible bonded structures (e.g., comprising one or more dies hybrid bonded to a flexible hybrid bonding substrate) described below, may allow non-planar die and/or height variation without disrupting electrical connection between components. In some embodiments, multilayer flexible hybrid bonding substrates or layers can provide a higher tolerance of non-planar die and/or height variation compared to single layer flexible bonded structures.

### Example Flexible Hybrid Layers and Substrates

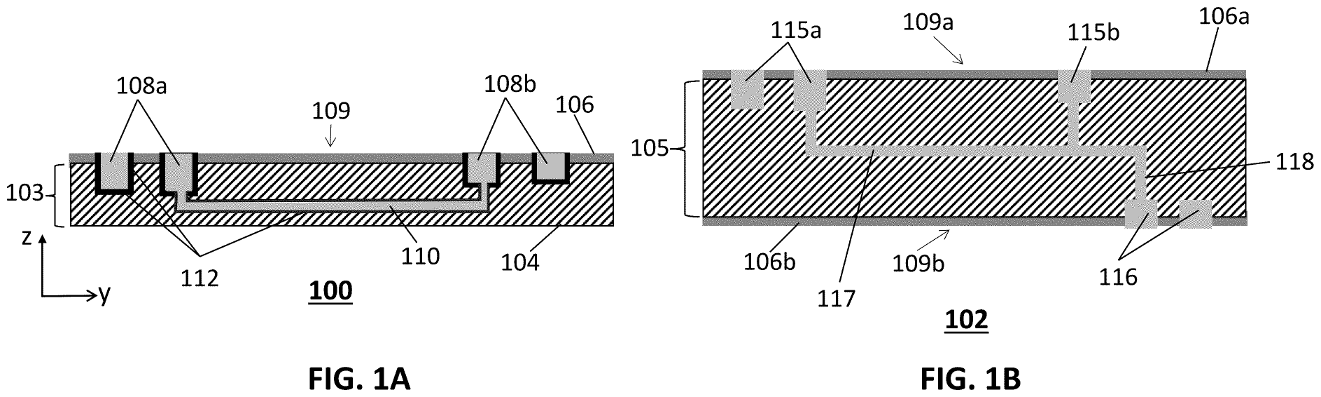

FIG. 1A schematically illustrates an example flexible hybrid bonding structure 100 comprising a flexible layer 103 and a dielectric bonding layer 106 (also referred to as dielectric layer) disposed on the flexible layer 103. In some embodiments, a dielectric bonding layer 106 may comprise two or more dielectric sub-layers. In some examples, these sub-layers may comprise the same or different dielectric materials). The flexible hybrid bonding structure 100 may further comprise two or more contact pads 108a, 108b at least partially formed in the flexible layer 103 and extending through the bonding layer 106 to a hybrid bonding surface 109 of the dielectric layer 106. In some cases, the flexible layer 103 may comprise an organic material (e.g. polymer, polyimide, PBO, resin, epoxy, etc.) and the dielectric layer 106 may comprise an inorganic dielectric material (e.g., silicon oxide, silicon nitride, silicon oxynitride, silicon carbonitride. silicon oxycarbonitride, silicon carbide, spin-on-glass etc.). In some embodiments, a contact pad 108a in the first section of the flexible hybrid bonding structure 100 may be electrically connected to a contact pad 108b in the second section of the flexible hybrid bonding structure 100 via a conductive line 110 embedded in the flexible layer 103. In some embodiment, the conductive line 110 may comprise multilayer conductive lines. In some embodiments, the conductive line 110 may comprise multiple layers connected though conductive vias embedded in the flexible layer 103. In some such embodiments, flexible hybrid bonding structure 100 may electrically connect a first component that is electrically connected to the first contact pad 108a to a second component that is electrically connected to a second contact pad 108b. The first component may be hybrid bonded to a first region of the hybrid bonding surface 109 above the first section and the second component may be hybrid bonded to a second region of the hybrid bonding surface 109 above the second section. In some examples, the conductive line 110 is at least partially embedded in the flexible layer 103. In some embodiments, a barrier layer 112 may separate contact pads 108a, 108b and/or a conductive line 110 of the flexible hybrid layer 102 from the flexible layer 104 and/or a dielectric bonding layer 106. For example, the contact pads 108a, 108b, and/or the conductive line 110 may be formed in an opening having a barrier layer lining. In some examples, the barrier layer 112 may comprise a dielectric material. In some cases, the dielectric bonding layer 106 and barrier layer 112 may comprise substantially the same material (e.g., a dielectric material) or have similar compositions. In some cases, the dielectric bonding layer 106 and barrier layer 112 may comprise different material or have different compositions. In some embodiments, the barrier layer 112 may comprise a conductive material. In some examples, the barrier layer 112 may be configured to protect the corresponding contact pad by blocking or reducing transport of the certain species (e.g., water molecules or gas) from the flexible layer 103 to the contact pad and vice versa. In some examples, the barrier layer 112 can prevent copper migration from the contact pads 108a, 108b and the conductive line 110 into the flexible layer 103 and the dielectric bonding layer 106. In some embodiments, the dielectric bonding layer 106 may comprise two or more dielectric sub-layers. For example, the dielectric bonding layer 106 may comprise a first dielectric sub-layer (e.g., an intermediate or coupling sub-layer) disposed directly on the flexible layer 103 and a second dielectric sub-layer (e.g., a bonding sub-layer) may be disposed over the coupling dielectric. In some embodiments, first dielectric sub-layer can be different from the second dielectric sub-layer.

In some cases, at least a portion of the flexible layer 103 extending from the first section to the second section of the flexible hybrid layer 102 may comprise a flexible, mechanically deformable, or otherwise a compliant material as described above. Advantageously, the double-sided flexible hybrid bonding structure 100 may provide a deformable electrical connection between two, three, or more components hybrid bonded to different regions of the surface 109.

FIG. 1B schematically illustrates another example double-sided flexible hybrid bonding structure 102 comprising a flexible layer 105, and two dielectric layers (dielectric bonding layers) 106a, 106b, disposed on opposite main surfaces of the flexible layer 105. In some cases, the flexible layer 105 may comprise an organic material and the dielectric layers 106a, 106b may comprise inorganic dielectric materials. The first dielectric layer 106a may comprise a first hybrid bonding surface 109a comprising top surfaces of one or more contact pads 115a, 115b that are at least partially formed in an upper portion of the flexible layer 105. The second dielectric layer 106b may comprise a second hybrid bonding surface 109b comprising top surfaces and one or more contact pads 116 that are at least partially formed in a lower portion of the flexible layer 105. In some embodiments, the contact pad 115a formed in a first section of the upper portion of the flexible layer 105 may be electrically connected to the contact pad 115b formed in a second section of the upper portion of the flexible layer 105 via a conductive line 117. In some cases, the first section may be separated from the first section in a longitudinal direction parallel to a main surface of the flexible layer 105. In some embodiments, a contact pad 115a in the upper portion of the flexible layer 105 may be electrically connected to the contact pad 116 in the lower portion of the flexible layer 105 via a conductive line 118 and the conductive line 117. Advantageously, the double-sided flexible hybrid bonding structure 102 may provide a deformable electrical connection between two, three, or more components hybrid bonded to different regions of the first and second hybrid bonding surfaces 109a, 109b. For example, the flexible hybrid bonding structure 102 may electrically connect first, second, and third components electrically connected to the contact pad 115a, contact pad 115b, and contact pad 116, respectively. The first and second components may be hybrid bonded to first and second regions of the first hybrid bonding surface 109a in the upper portion of the flexible layer 105, respectively, and the third component may be hybrid bonded to a region of the second hybrid bonding surface 109b in the lower portion of the flexible layer 105. In some cases, the second, and third components may be placed at different vertical and lateral positions with respect to the first components. In some cases, the vertical and lateral positions may be defined with respect to a main plane or surface of the first components.

In various embodiments, flexible layer 103 or flexible layer 105 may comprise a deformable region configured to allow bending of the flexible hybrid bonding structure 100 or flexible hybrid bonding structure 102 such that at least to electrically connected contact pads are positioned in two different planes (e.g., two vertically separated planes). In some embodiments, the flexible substrate may be deformed to provide electrical connection between device contact pads (e.g., contact pads of two different devices) located within different planes or substrates. In some implementations, when the flexible hybrid bonding structure 100 or flexible hybrid bonding structure 102 are deformed a radius of curvature of the deformable region can be less than 100 times a thickness of the hybrid bonding structure, less than 50 times a thickness of the substrate and even less than 20 times a thickness of the substrate without disrupting an electrical connection between the device contact pads.

It should be understood that the single or double-sided flexible hybrid bonding structure are neither limited to the specific designs shown in FIGS. 1A-1B nor to configurations that include at least some of the features of these designs with respect to number of layers, placement of the contact pads, a number and/or location of flexible layers or deformable regions. Additional examples of flexible hybrid bonding structures may be found throughout provisional U.S. Patent Application Nos. 63/662994 and 63/663017 filed on Jun. 21, 2024, the entire contents of each of which are incorporated by reference herein in their entirety and for all purposes.

### Bonded Structures With Vertically Stacked Devices

In various applications, it can be advantageous to provide electrical connection between devices positioned at different vertical levels with respect to a substrate to increase the density of devices in a package or system while maintaining low loss and high bandwidth communication between these devices. In some examples, the arrangement of contact pads in these devices may not allow electrical connections between them using planar structures (e.g., planar interposers). For example, terminals and contact pads of an electronic chip may be positioned on a single main surface of the electronic chip. When such an electronic chip is mounted on a substrate and is electrically connected to the substrate (e.g., electronic board), its contact pads may be positioned on a bottom surface of the chip to be electrically connected to contact pads of the substrate. As such, in some cases, the mounted electronic chip may not be electrically connected to an electronic chip vertically separated from the substrate (e.g., above the electronic chip) via the substrate (e.g., a planar interposer). In some embodiments, the mounted electronic chip may include top contact pads positioned on a top surface of electronic chip (opposite to its bottom surface). In some examples, the top contact pads can be connected to the electronic chip by one or more through substrate vias (TSVes). In some such embodiments, the mounted electronic chip can be electrically connected to an electronic chip vertically separated from the substrate (e.g., above the electronic chip); however providing top contact pads on the electronic chip and forming TSVs extending from the bottom surface to the top surface of the electronic chip can be complicated and may significantly increase the fabrication cost of the chip and thereby may not be economically and/or technically viable.

Some of the structures disclosed below may allow electrical connection between devices (e.g., electronic chips) having contact pads arranged over different planes (e.g., vertically separated planes). Some embodiments, described below include flexible interposers that can be deformed to provide non-planar electrical connection between electronic devices having different vertical positions or different orientations with respect to a substrate (e.g., planar substrate) on or over which the electronic devices are mounted.

In should be understood that as defined herein, a vertical direction is a direction substantially normal to a main surface of substrate (e.g., a planar substrate, a planar interposer, or the like) and lateral and longitudinal directions (collectively referred to as a horizontal direction), are directions substantially normal to the vertical direction and thereby substantially parallel to the main surface of the substrate.

In some embodiments, a first plurality of contact pads of a flexible interposer within or over a first region of the flexible interposer may be electrically connected to a first device, a second plurality of contact pads of the flexible interposer formed within or over a second region of the flexible interposer may be electrically connected to a second device vertically separated from the first device or disposed on or over the first device, and a deformable region of the flexible interposer (e.g., extending between the first and second regions) may be deformed to maintain electrical connection between the first and second pluralities of the contact pads. In some examples, the first and second regions of the flexible interposer may be substantially parallel or tilted with respect to each other. In some examples, a flexible interposer may comprise one or more layers extended in a longitudinal direction, a first surface region comprising conductive surfaces of the first plurality of contact pads, a second surface region longitudinally separated from the first region and comprising conductive surfaces of the second plurality of contact pads, and a deformable region at least partially positioned between the first and second surface regions. The flexible interposer may further comprise one or more conductive lines longitudinally extending from the first surface region to the second surface region and providing electrical connection between the first and second pluralities of contact pads. In some examples, the conductive lines can be at least partially embedded in the flexible interposer. In some examples, one or more conductive lines can be formed in a sub-layer of the flexible interposer (e.g., a middle sub-layer). In some examples, the one or more conductive lines can at least partially overlap with the deformable region of the flexible interposer such that when the flexible interposer is bent, curved or otherwise deformed, the electrical connection between the first and second pluralities of the contact pads is preserved. In some implementations, the first and second surface regions may be formed on a single main surface of the flexible interposer. In some implementations, the first and second surface regions may be formed on two opposite main surfaces of the flexible interposer.

In various embodiments, the electrical connection between the first and devices and the flexible interposer may be provided via different bonding and interconnection methods and configurations including, but not limited to, direct hybrid bonding (described above) and thermal compression (TC) bonding.

In some examples, at least one of the main surfaces of a flexible interposer may be configured for bonding using TC bonding. In some cases, thermal compression (TC) bonding may comprise bonding two conductive (e.g., metallic surfaces) by bringing them into contact and applying force and heat to form bond (e.g., a diffusion bond, an atomic bond, etc.). In various embodiments, contact pads that are bonded using TC bonding may comprise copper (Cu), gold (Au), and aluminum (Al), or other metals.

In some examples, at least one of the main surfaces of a flexible interposer may be configured for bonding and electrical connection to a device using soldering. For example, a fusible metal alloy (e.g., (e.g., an array of solder bumps) can be provided between the contact pads in the main surface and the device, heated to melt the alloy, and cooled to form the connection between the main surface and the device. In some examples, the main surfaces of a flexible interposer may be configured for bonding and electrical connection to a device using soldering micro-bumped flip chip and/or thermo-compression flip chip using solder capped Cu/Ni as conductive adhesive or another lead-free solder or eutectic solder.

In some embodiments, a flexible interposer may comprise one or more features described above with respect to the hybrid bonding structures 100, 102. However, the embodiments are not so limited and flexible interposers may comprise other structures, features, and configurations including, but not limited to, the flexible hybrid bonding structures described in provisional U.S. Patent Application Nos. 63/662994 and 63/663017 filed on Jun. 21, 2024, the entire contents of each of which are incorporated by reference herein in their entirety and for all purposes.

In some examples, at least one of the main surfaces of a flexible interposer may comprise a hybrid bonding surface configured for direct hybrid bonding based on DBI® bonding process described above. In some such examples, at least one of the devices may be directly bonded to the hybrid bonding surface of a flexible interposer to form a direct bonding interface (DBI) providing electrical connection between two devices positioned at different vertical levels with respect to a substrate through a bent portion of the flexible

Advantageously, using flexible interposers to provide electrical connection between different devices of a system may increase the functionality of the packaged system by improving speed and bandwidth (e.g., by reducing the length of the interconnects) and reduce the size of the system or package by increasing the density of interconnected devices on a substrate or board (e.g. a printed circuit board).

Some of the embodiments disclosed herein, may allow efficient cooling of vertically stacked and electrically connected devices. For example, a flexible interposer may be used to electrically connect a first device mounted over and electrically connected to a substrate to a second device positioned above the first device via a bottom surface of the first device and top surface of the second device allowing the top surface of the first device and the bottom surface of the second device to be used for cooling these devices. For example, a cooling device may be disposed (e.g., sandwiched) between the top surface of the first device and the bottom surface of the second device. In some cases, the cooling device may be configured to absorb thermal energy from one or both of the first and second devices.

In some embodiments, the structures, configurations, and flexible interposers disclosed herein may be used to electrically connect two or more electronic devices. The one or more electronic devices (herein referred to as devices) may comprise integrated electronic circuits, electronic chips, electronic dies, or otherwise a monolithically fabricated electronic circuit. In some implementations, flexible interposers disclosed herein may be used to electrically connect one or more memory devices (e.g., memory chips, memory dies, memory stacks or the like) to an electronic processor chip (also referred to as processor chip). In some embodiments, the processor chip may comprise a central processing unit (CPU) or a graphical processing unit (GPU). In some embodiments, a memory device may comprise one or more HBM (high bandwidth memory) dies, herein referred to as HBM memory device. A high bandwidth memory die comprise a plurality of vertically stacked memory chips. In some cases, a HBM device may comprise a vertical stack of HBM dies electrically connected to each other (e.g., micro solder bumps and/or vertical vias). In some examples, a vertically stacked memory chip may be referred to as a memory stack. In some embodiments, CPU and/or GPU, may be electrically connected to one or more HBM memory devices by one or more interposers. In some cases, at least one of the HBM memory devices may be positioned (e.g., mounted or bonded) above the processor chip and can be electrically connected to the processor chip via a flexible interposer. In some implementations, a portion of the flexible interposer between the processor chip and the HBM memory device may comprise a bent and out of plane layer. In some implementations, the processor chip may be electrically connected to a second HBM memory device by a planar interposer. In some embodiments, a processor chip can be electrically connected to a first plurality of HBM memory devices via a planar interposer, on which the processor chip and first plurality of HBM memory devices are mounted, and to a second plurality of HBM memory devices vertically separated from the planar interposer by at least the processor chip via a plurality of flexible interposers.

It should be understood that in different embodiments an electrical connection between two devices, e.g., a memory device and a processor chip may comprise an electrical connection between a plurality of pins, contact pads, or terminals of a one device and those of the other device. Such electrical connection may comprise a high bandwidth communication link (e.g., data communication link) between these devices. In some cases, such electrical connection may comprise a multibit communication link established, e.g., by parallel conductive lines. In some examples, the communication link established by a flexible interposer, a planar interposer, or a direct connection between two devices (e.g., via contact pads and conductive vias of the devices) can be a data communication channel having a channel width of greater than 64-bit, greater than 128-bit, greater than 512-bit, greater than 1024 bit. In some cases, the channel width of the data communication channel can be from 8-bit to 16-bit, from 16-bit to 32-bit, from 32-bit to 64-bit, from 64-bit to 128-bit from a 28-bit to 256-bit, from 256-bit to 512-bit, or any ranges formed by these values or larger or smaller. In some examples, the bandwidth (or speed) of a communication link established by a flexible interposer, a planar interposer, or a direct connection between two devices (e.g., via contact pads and conductive vias of the devices) can be greater than 10 GB/sec, greater than 100 GB/sec, greater than 500 GB/sec, greater than 1000 GB/sec, or greater.

In some embodiments, a processor chip may comprise contact pads that allow electrical connection to the processor chip through two opposite major surfaces of the processor chip. In these embodiments, a memory device can be electrically connected to the processor chip via a plurality of contact pads disposed at the top surface of the processor chip. The plurality of contact pads may be configured to establish a high bandwidth data communication link or channel between the second memory device and the processor chip. In some cases, the processor chip may further comprise a plurality vertical conductive vias (e.g. through silicon vias or TSVs) configured to electrically connect the memory device disposed on top and electrically connect to the processor chip, and to a substrate on which the processor chip is mounted.

In some implementations, electrically connecting a memory device (e.g., HBM) on a top major surface of a processor chip that is electrically connected to a substrate may require a modified processor chip architecture to manage the additional thermal energy generated by the memory device mounted on top. In some embodiments, when the processor chip is electrically connected to two memory devices one of which is mounted on top of the processor chip, the communication bandwidth between the memory devices and the processor can be doubled without increasing the package footprint.

In some embodiments, two or more memory devices placed at different lateral positions with respect to the processor chip can be in communication with the processor chip via a substrate (e.g., an interposer, a flexible interposer). In some such embodiments, one or more of these memory devices can be hybrid bonded (directly bonded) to a top surface of the substrate. For example, the bonded structures 200, 202, may comprise at least one additional memory device electrically connected to the interposer 204 or the substrate 220, and mounted on the left side of the processor chip 201 (opposite the third device 207 which can be an HBM). In some cases, a bonded structure may comprise a processor chip mounted on, and electrically connected to, a substrate, at least one memory device mounted on the processor chip (e.g., a top surface of the processor chip opposite to the substrate) and electrically connected to the processor chip, and two or more memory devices mounted on the substrate at different lateral positions with respect to the processor chip and electrically connected to the processor chip. In some cases, the at least one memory device mounted on the processor chip can be electrically connected to the processor chip via TSVes formed in the processor chip, and the two or more memory devices mounted on the substrate at different lateral positions with respect to the processor chip and electrically connected to the processor chip through the substrate. Advantageously, when a processor chip is connected to memory devices mounted on the substrate and on top of the processor chip, the processor chip may have access to memory devices with a larger data communication bandwidth as, a larger number of memory devices may be electrically connected to the processor chip via short and high bandwidth communication links (e.g., established TSVes for memory device on the top surface of the memory chip and short conductive traces for the memory devices mounted on the substrate).

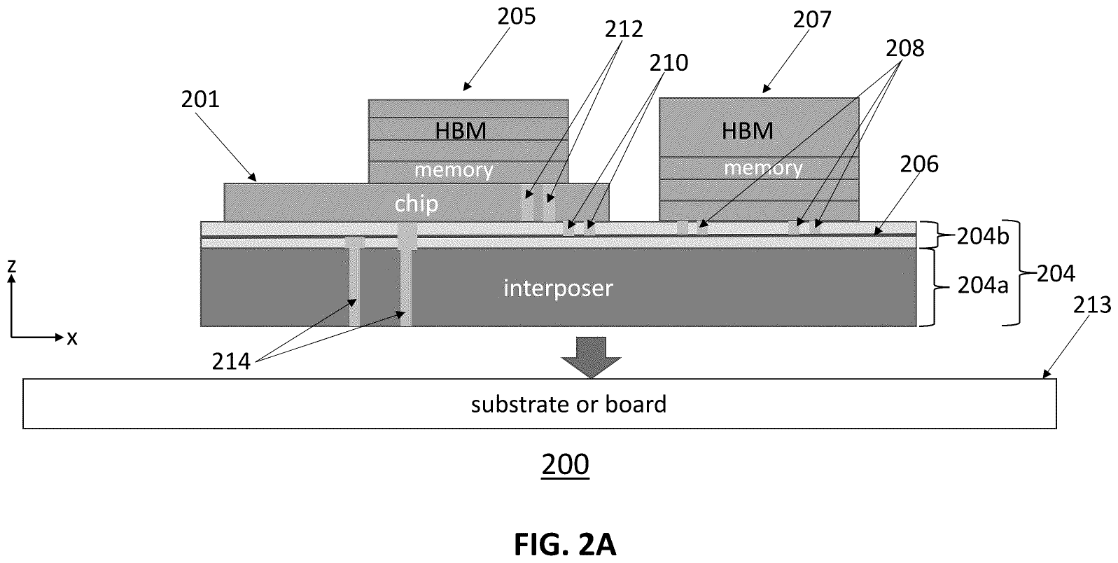

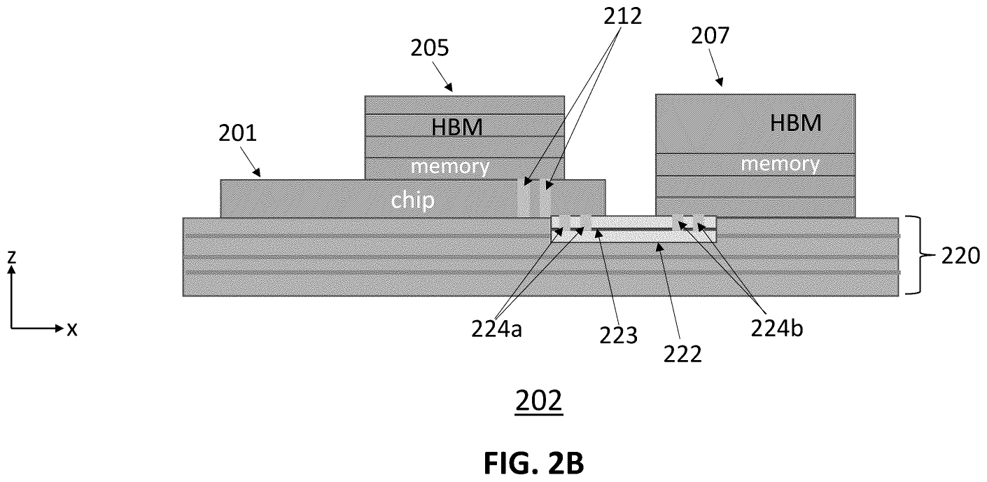

FIG. 2A depicts a side cross-sectional view of a bonded structure 200 formed on an interposer 204 (e.g., a planar interposer). In some cases, bonded structure 200 may comprise a first device 201 electrically connected to the interposer 204, a second device 205 mounted on top of the first device 201 (e.g., contact pads, through silicon vias, and/or micro solder bumps), and a third device 207 mounted on the interposer 204.

In some embodiments such as embodiments shown in FIG. 2A, the first device 201 may comprise contact pads formed near a bottom surface of the first device 201 (facing the interposer 204) and contact pads formed near a top surface of the first device 201. In these embodiments, the first device 201 can be electrically connected to the second device 205 via the contact pads near the top surface and to the interposer via the contact pads near the bottom surface.

In various embodiments, a chip, a die, or device can be mounted face up or face down, e.g., with the active side facing up or down. In some implementations, a chip, a die, or device may comprise an active front side or bottom surface closer to active circuitry (e.g., a circuitry comprising transistors and other active electronic device), and a back or top side opposite to the front side or bottom side.

In some embodiments, the first device 201 may comprise a processor chip (e.g., a CPU, a GPU, or the like) and the second and third devices 205, 207 can be memory devices (e.g., HBM memory devices including a stack of memory dies bonded to a logic controller die). In some embodiments, the interposer 204 may include several groups of contact pads at different locations over the interposer 204 and conductive lines that provide electrical connections between different groups of contact pads. In the example shown, the interposer 204 comprises a first plurality of contact pads 210 within a first region of the interposer 204, a second plurality of contact pads 208 within a second region of the interposer 204 and conductive lines 206 that extend in a longitudinal direction from the first region to the second region and electrically connects the first and second pluralities of the contact pads 210, 208.

In some embodiments, the interposer 204 may comprise a base layer 204a and a top layer 204b (e.g., a routing layer) where the top layer 204b is configured to be bonded to different devices that are electrically connected by the interposer 204. In some implementations, the conductive lines 206 and the contact pads of the interposer 204 may be at least partially formed in the top layer 204b. In some embodiments, the base layer 204a can comprise a semiconductor (e.g., silicon) or dielectric (e.g., glass, organic substrate, etc.) substrate. In some embodiments, the base layer 204a may comprise a reconstituted structure (e.g., a structure with one or more devices encapsulated in a dielectric encapsulant).

In some embodiments, the top layer 204b may comprise a hybrid bonding surface configured to allow hybrid bonding a device (e.g., the first or the third devices 201, 207) to the interposer 204. For example, the top surface of the top layer 204b may include a hybrid bonding comprising surface dielectric bonding regions of the top layer 204b and conductive surface regions of the first and second pluralities of the contact pads 210, 208. In some embodiments, the top layer 204b may comprise a surface configured for TC bonding a device (e.g., the first or the third devices 201, 207) to the interposer 204. For example, the top surface of the top layer 204b may comprise conductive surface regions (e.g., conductive surface regions of the first and second pluralities of the contact pads 210, 208) configured for TC bonding to conductive surface regions of the first and third devices 201, 207. In various embodiments, the interposer 204 may comprise one or more features described above with respect to the hybrid bonding structures 100, 102.

In some implementations, interposer 204 may be mounted on or over (e.g., soldered to or directly bonded to) a substrate or board (e.g., a printed circuit board, a ceramic substrate, a semiconductor or dielectric interposer, etc.) 213. In some examples, a bottom surface of the interposer 204 may comprise contact pads that are electrically connected to one or more contact pads formed near the top surface of the interposer 213, e.g., via conductive vertical vias 214 and/or laterally or longitudinally extended conductive lines within the interposer 204 (e.g., conductive lines 206).

It should be understood, that while in FIG. 2A conductive vertical vias 214 and 212 each include two conductive vertical vias, the interposer 204 and the chip 201 each may include a plurality of vias distributed across different regions of the interposer 204 and the chip 201.

FIG. 2B depicts a side cross-sectional view of another bonded structure 202 formed on a substrate 220 (e.g., a package substrate, an organic substrate, or the like) having an interconnect region embedded in a substrate. In some cases, bonded structure 202 may comprise a first device 201 electrically connected to a second device 205 mounted on top of the first device 201 (e.g., contact pads, vias, and/or micro solder bumps), and to a third device 207 mounted on the substrate 220 via the embedded interconnect bridge 222 (e.g., an embedded bridge). In some embodiments, embedded interconnect bridge 222 may comprise a semiconductor (e.g., silicon) or dielectric (e.g., glass) bridge comprising a silicon layer having a plurality of conductive lines configured to electrically connect the first and third devices 201, 207. In some examples, embedded interconnect bridge 222 may be extended along a longitudinal direction from a first end near a first region (e.g., first surface region) of the substrate 220, on which the first device 201 is disposed (e.g., mounted or bonded), to a second end near a second region (e.g., second surface region) of the substrate 220, on which the third device 207 is disposed. In some examples, embedded interconnect bridge 222 may comprise a first plurality of contact pads 224a formed in the embedded interconnect bridge 222 near the first end, a second plurality of contact pads 224b formed in the embedded interconnect bridge 222 near the second, and plurality of conductive lines 223 electrically connecting the first and second pluralities of the contact pads 224a, 224b.

In some embodiments, such as embodiments shown in FIG. 2B, the first device 201 may comprise contact pads formed near a bottom surface of the first device 201 (facing the substrate 220) and contact pads formed near a top surface of the first device 201. In these embodiments, the first device 201 can be electrically connected to the second device 205 via the contact pads near the top surface and the to the embedded interconnect bridge or embedded bridge 222 via the contact pads near the bottom surface. In some embodiments, substrate 220 can be an organic substrate (e.g., a PCB substrate, epoxy material, resin, or the like). In some embodiments, embedded bridge 222 or a bridge chip may be embedded (or reconstituted) within the organic dielectric to form a reconstituted wafer or panel acting as substrate 220. In some embodiments, bridge 222 can have through substrate vias (e.g. through silicon vias or TSVs) and redistribution layer on top and bottom side of the bridge chip. In some embodiments, RDL is formed on top or bottom surfaces of the substrate 220. A bonding layer (e.g., an inorganic bonding layer such as silicon oxide) can be provided on the substrate 220, for example, if devices are to be directly bonded to the substrate.

In various embodiments, the first and third devices 201, 207, may be bonded on a top main surface of the substrate 220 using hybrid bonding (DBI® bonding) or TC bonding. For example, in some embodiments, the top substrate of 220 and/or a top surface of the embedded interconnect bridge 222 may comprise a hybrid bonding surface configured for direct bonding to the first and third devices 201, 207. In some examples, the first and third devices 201, 207, may be bonded using soldering (e.g., electrical and mechanical connections provided by an array of solder bumps). In some examples, the substrate 220 can be a flexible substrate comprising one or more features described above with respect to FIGS. 1A-1B.

In some embodiments, the first device (e.g., the processor chip) may comprise conductive vertical vias 212 extending from contact pads formed on a bottom surface of the first device 201 (facing the interposer 204) to contact pads formed on a top surface of the first device 201 to provide direct electric connection between the second device 205 and the interposer 204.

With continued reference to FIG. 2B, in some embodiments, a bottom surface of the second device 205 and a top surface of the first device 201 may comprise hybrid bonding surfaces configured to allow hybrid bonding of the second device 205 on the first device 201 and thereby electrically connecting the first and second devices 201, 205, via direct bonding interfaces formed between dielectric regions and conductive surface regions of the respective hybrid bonding surfaces.

In various embodiments, various configuration (e.g., bonded structures 200, 202), that include memory stacks (HBMs) both on the substrate (laterally separated from the processor chip 201) and on top of the processor chip (vertically separated from the processor chip 201), may double the bandwidth of processor-memory communication without giving up on the package footprint. In should be understood, that the bonded structures 200, 202, are non-limiting examples, and in various implementations, multiple memory devices (memory stacks) may be mounted on and be electrically in communication with the processor chip 201 and multiple memory devices (memory stacks) may be mounted on the substrate and be electrically in communication with the processor chip 201 (e.g., on different sides of the processor chip 201). In some embodiments, one or more of TSVs, wiring layers, redistribution layers (not shown) may be provided on top of processor chip 201 (e.g., a GPU), the processor chip 201 can be electrically connected to more memory stacks without increasing wiring complexity between the interposer and the processor chip 201.

As described above, in some embodiments, a flexible interposer may be used to provide electrical connection between devices positioned at different vertical levels or with different orientations with respect to each other and with respect to a substrate or planar interposer on which one of the devices is disposed (e.g., mounted or bonded). In the embodiments described below, configuration of contact pads in a first device disposed on the substrate (or the planar interposer) may not allow simultaneous electrical connection of the first device (e.g., a processor chip) to the substrate (or the interposer) and to a second device (e.g., a memory chip) disposed above the first device. A flexible interposer may provide such electrical connection by establishing a non-planar electrical connection between the first and second devices.

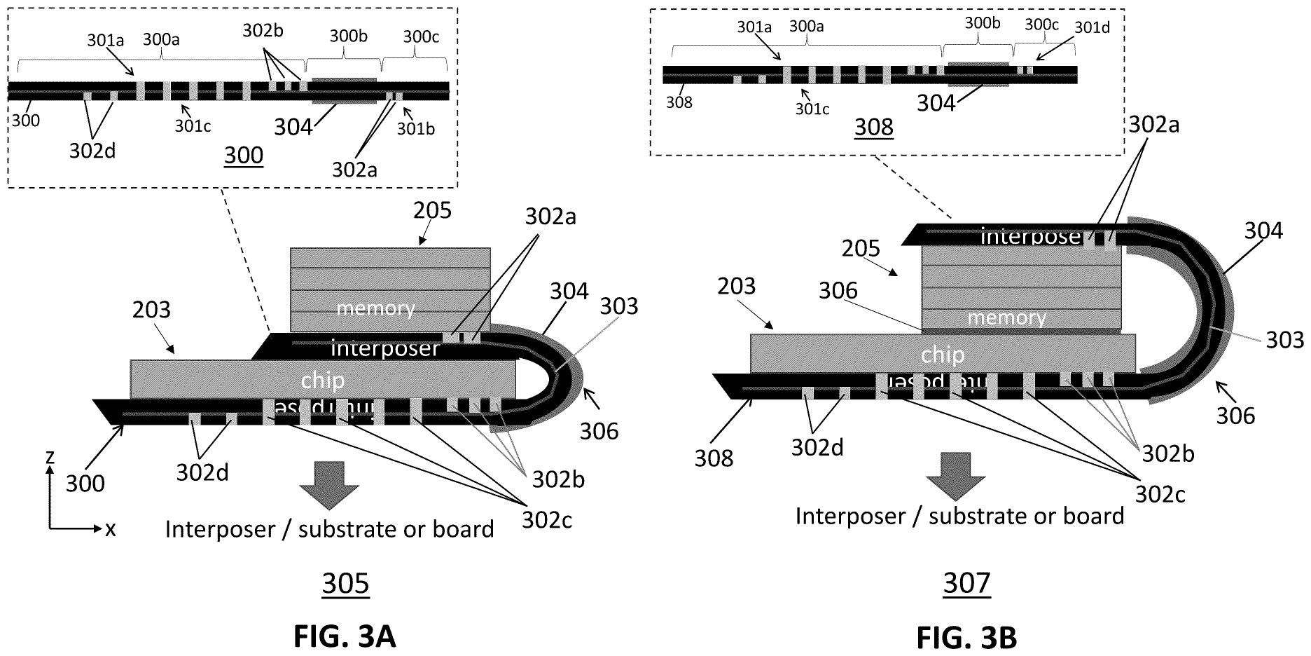

FIG. 3A depicts a side cross-sectional view of a bonded structure 305 comprising a first device 203, a second device 205 positioned above the first device 203, and a bent flexible interposer 300 providing electrical connection between the first and the second devices 203, 205. In various implementations, the first, second, and third devices, 203, 205 and 207 may comprise electronic devices such as electronic chips, electronic dies, and the like.

In some examples, the first device 203 may comprise a processor chip (e.g., a CPU, a GPU or the like) and the second device 205, may comprise a memory device (e.g., HBM memory devices). In some embodiments, the contact pads of the first device 203 be arranged near a bottom surface of the first device 203. As such the electronic circuitry of the first device may not be accessible via two opposite major surfaces of the first device 203. In some embodiments, the first device 203 may not include vertically vias (e.g., through-silicon vias) extending between the two opposite major surfaces (e.g., top and bottom surfaces).

In some embodiments, the flexible interposer 300 may comprise a first interposer portion 300a below the first device 203, a second interposer portion 300c between the first and second devices 203, 205 (e.g., between a top surface of the first device and a bottom surface of the second device 205), and a middle interposer portion 300b extended between the first and second interposer portions 300a, 300c. In some examples, the first and second portions 300a, 300c may be longitudinal portions extended in directions substantially parallel to a main surface of the first device 203 (e.g., parallel to x-axis) and the middle interposer portion 300b may comprise a bent portion (or non-planar portion) 304. In some implementations, the first interposer portion 300a may be bonded and electrically connected to a bottom surface of the first device 203 and the second interposer portion 300c may be bonded and electrically connected to the second device 205. In the bonded structure 305, a top surface 301a of the first portion is be bonded and electrically connected to the bottom surface of the first device 203 and a bottom surface 301b of the second interposer portion may be bonded and electrically connected to a bottom surface of the second device 205. The inset in FIG. 3A schematically illustrates the flexible interposer 300 (depicting corresponding interposer portions 300a, 300b, 300c) prior to bending and being included in the bonded structure 305. In some implementation, the middle interposer portion 300b (that becomes the bent portion 306) may comprise a cladding layer 304 configured to provide mechanical support and to protect the bent portion 306 and the conductive lines 303 therein from fracture and/or development of mechanical defects and discontinuities in the flexible interposer. In some embodiments, the cladding layer may comprise polyimide, PBO, epoxy, resin or another dielectric layer. In some examples, thickness of the cladding layer 304 can be from 0.5 to 50 microns. In some embodiments, the cladding material is disposed around the interposer portion 300b via molding (e.g. transfer or compression molding of epoxy) or by capillary action (e.g. underfill).

In some embodiments, the second device 205 may be vertically separated from the first device 203 by the second interposer portion 300c of the flexible interposer 300, such that the second interposer portion 300c of the flexible interposer 300 is disposed vertically between the first device 203 and the second device 205. As such, the first device 203 (e.g., the processor chip) may be at least partially sandwiched between the first and second interposer portions 300a, 300c of the flexible interposer 300.In some such embodiments, a bottom surface of the flexible interposer 300 (e.g., bottom surface 301b of the second interposer portion 300c) may be bonded to the second device 205 (e.g., a bottom surface of the second device 205). In some embodiments, a top surface of the flexible interposer 300 (e.g., top surface of the second interposer portion 300c opposite to the bottom surface 301b) may be bonded to a top surface of the first device 203.

In some embodiments, the second device 205 may be vertically separated from the first device 203 by the second interposer portion 300c of the flexible interposer 300 and another layer or device (e.g., a chip) disposed between the first device 203 and the second interposer portion 300c. In some examples, the other layer or device may be bonded to the second interposer portion 300c and the first device.

In some embodiments, the flexible interposer 300 may comprise a first plurality of contact pads 302a within the second interposer portion 300c, and second, third, and fourth pluralities of contact pads 302b, 302c, and 302d within the first interposer portion 300a. In some such embodiments, the first plurality of contact pads 302a may be electrically connected at least to the second plurality of contact pads 302b. In some embodiments, the first plurality of contact pads 302a may be electrically connected to the third and fourth pluralities of contact pads 302c, 302d.

In some implementations, the first plurality of contact pads 302a may be formed near a bottom surface 301b of the second interposer portion 300c to provide electrical connection to the flexible interposer via the bottom surface 301b. In some implementations, the second plurality of contact pads 302b may be formed near a top surface 301a of the first interposer portion 300a to provide electrical connection to the flexible interposer via the top surface 301a. In some implementations, the third plurality of contact pads 302c may comprise vertically vias extended from a bottom surface 301c of the first interposer portion 300a to the top surface 301a to provide electrical connection to the flexible interposer via top and bottom surfaces 301a, 301c, and additionally provide electrical connection between the first device and a substrate, interposer, or board on which the bonded structure 305 is bonded or mounted. In some implementations, the fourth plurality of contact pads 302d may be formed near the bottom surface 301c to provide electrical connection to the flexible interposer via the bottom surface 301c.

In some implementations, the flexible interposer 300 may comprise conductive lines 303 that electrically connect the first plurality of contact pads 302a to the second pluralities of contact pads 302b and, in some cases, to the third and fourth pluralities of contact pads 302c, 302d.

In some embodiments, the first interposer portion 300a of the flexible interposer 300 may be hybrid bonded to the first device 203 to electrically connect the second plurality of contact pads 302b and, in some cases, the third plurality of contact pads 302c, to the first device 203. For example, the top surface 301a of the first interposer portion 300a may comprise a hybrid bonding surface formed by the dielectric surface regions of the flexible interposer 300 and the conductive surface regions of the second plurality of contact pads 302b and, in some cases, the third plurality of contact pads 302c.

In some embodiments, the second interposer portion 300c of the flexible interposer 300 may be hybrid bonded to the second device 205 to electrically connect the first plurality of contact pads 302a to the second device 205. For example, the bottom surface 301b of the second interposer portion 300c may comprise a hybrid bonding surface formed by the dielectric surface regions of the flexible interposer 300 and the conductive surface regions of the first plurality of contact pads 302a.

In some embodiments, the first portion 300a of the flexible interposer 300 may be TC bonded to the first device 203 to electrically connect the second plurality of contact pads 302b and, in some cases, the third plurality of contact pads 302c, to the first device 203. In some embodiments, the second interposer portion 300c of the flexible interposer 300 may be TC bonded to the second device 205 to electrically connect the first plurality of contact pads 302a to the second device 205.

In some embodiments, the bonded structure 305 may be mounted on or bonded to a substrate, a board, or another interposer (e.g., interposer 204 described above with respect to bonded structure 200).

FIG. 3B depicts a side cross-sectional view of a bonded structure 307 comprising a first device 203, a second device 205 positioned above the first device 203, and a bent flexible interposer 308 providing electrical connection between the first and the second devices 203, 205. In various implementations, bonded structure 307 may comprise one or more features described above with respect to bonded structure 305. In the embodiment shown in FIG. 3B, the first device 203 and the second device 205 (e.g., the processor chip and memory device) are sandwiched between the first and second interposer portions 300a, 300c of the flexible interposer 308.

In some embodiments, flexible interposer 308 may comprise one or more features described above with respect to flexible interposer 300 however the first plurality of the contact pads 302a of the flexible interposer 308 are formed near a top surface 301d of the second interposer portion 300c to provide electrical connection to the flexible interposer 308 via its top surface. In some embodiments, the flexible interposer 308 may comprise a first interposer portion 300a below the first device 203, a second interposer portion 300c above the first device 205 (e.g., on the top surface of the first device 203), and a middle interposer portion 300b extended between the first and second interposer portions 300a, 300c. Similar to bonded structure 305, the first and second interposer portions 300a, 300c of the flexible interposer 308 may be longitudinal portions extended in directions substantially parallel to a main surface of the first device 203 (e.g., parallel to x-axis) and the middle interposer portion 300b may comprise a bent portion (or non-planar portion) 304. In some implementations, the first portion 300a may be bonded and electrically connected to bottom surface of the first device 203 and the second interposer portion 300c may be bonded and electrically connected to the second device 205. In the bonded structure 307, a top surface 301a of the first portion is be bonded and electrically connected to the bottom surface of the first device 203 and a top surface 301d of the second interposer portion 300c may be bonded and electrically connected to a top surface of the second device 205. The inset in FIG. 3B schematically illustrates the flexible interposer 308 (depicting corresponding interposer portions 300a, 300b, 300c) prior to bending and being included in the bonded structure 307.

In various embodiments, a radius of curvature of the bent portion 306 in the bonded structure 305 can be smaller than 70%, smaller than 60%, smaller than 50% of the thickness of first device 203. In various embodiments, a radius of curvature of the bent portion 306 in the bonded structure 307 can be smaller than 70%, smaller than 60%, smaller than 50% of the combined thickness of first device and second devices 203, 205.

With continued reference to FIG. 3B and the bonded structure 307, in some examples, the second device 205 may be mounted, or bonded on a top surface of the first device 203, e.g., by an adhesive layer 309 (e.g., organic die attach material, non-conductive film (NCF) or non-conductive paste (NCP), or any other suitable adhesive layer). In some examples, the second device 205 can be vertically separated from the first device 203 by another layer or device (e.g., a chip) disposed between the first device 203 and the second device 205.

In various implementations, material composition of middle interposer portion 300b can be similar or different from those of the first and second interposer portions 300a, 300c.

In some embodiments, the flexible interposers 300 and 308 may comprise a non-conductive layer (e.g., a dielectric or semiconductor layer) and the contact pads 302a, 302b, 302c, 302d, and the conductive lines 303 may be formed in the non-conductive layer. In some examples, some of the conductive lines 303 may be formed on top or bottom surface of the non-conductive layer. In some examples, the non-conductive layer may comprise silicon, silicon dioxide, silicon nitride, silicon oxynitride, silicon carbonitride or other inorganic dielectric materials. In some examples, at least a portion of the non-conductive layer (e.g., the middle interposer portion 300b) may comprise an organic material (e.g., a polymer, a resin, epoxy, polyimide, PBO, etc.).

In some embodiments, the flexible interposer 300 (or 308) may comprise a single elongated non-conductive layer having a thickness less than 20 microns, less than 40 microns, less than 60 microns, less than 70 microns, or less than 100 microns.

In various implementations, the flexible interposers 300 and 308 may comprise two or more sublayers having different compositions. In some examples, one of the sub-layers may comprise an inorganic material. In some embodiments, the combined thickness of the flexible interposers 300 and/or 308 with two or more sublayers can be less than 20 microns, less than 40 microns, less than 60 microns, less than 70 microns, or less than 100 microns

In some embodiments, the deformability of the middle interposer portion 300b may be associated with a thickness of the flexible interposer 300 (or 308). For example, for a given composition of the flexible interposer 300 the thickness of the flexible interposer 300 can be smaller than a threshold value to allow formation of the bent portion 306 having a desired radius curvature while providing a stable electrical connection via the bent portion 306. As such, in some examples, threshold thickness value may be determined based at least in part on the composition of the middle interposer portion 300b, and one or both thicknesses of the first and second devices 203, 205).

In some embodiments, the deformability of the middle interposer portion 300b may be associated with a thickness of the middle interposer portion 300b. For example, for given composition of the middle interposer portion 300b the thickness of the middle interposer portion 300b can be smaller than a threshold thickness value to allow formation of the bent portion 306 having a desired radius curvature while providing a stable electrical connection via the bent portion 306. As such, in some examples, threshold thickness value may be determined based at least in part on the composition of the middle interposer portion 300b, and one or both thicknesses of the first and second devices 203, 205).

In some embodiments, interposer 300 (or 308) may comprise a thin semiconductor layer material (e.g., a thin silicon layer having a thickness in a range of 0.1 to 50 microns) or a thin dielectric layer (e.g., a thin glass layer, thin dielectric (organic or inorganic), or generally a thin non-conductive layer having a thickness in a range of 0.05 to 20 microns.

### Fabrication Steps

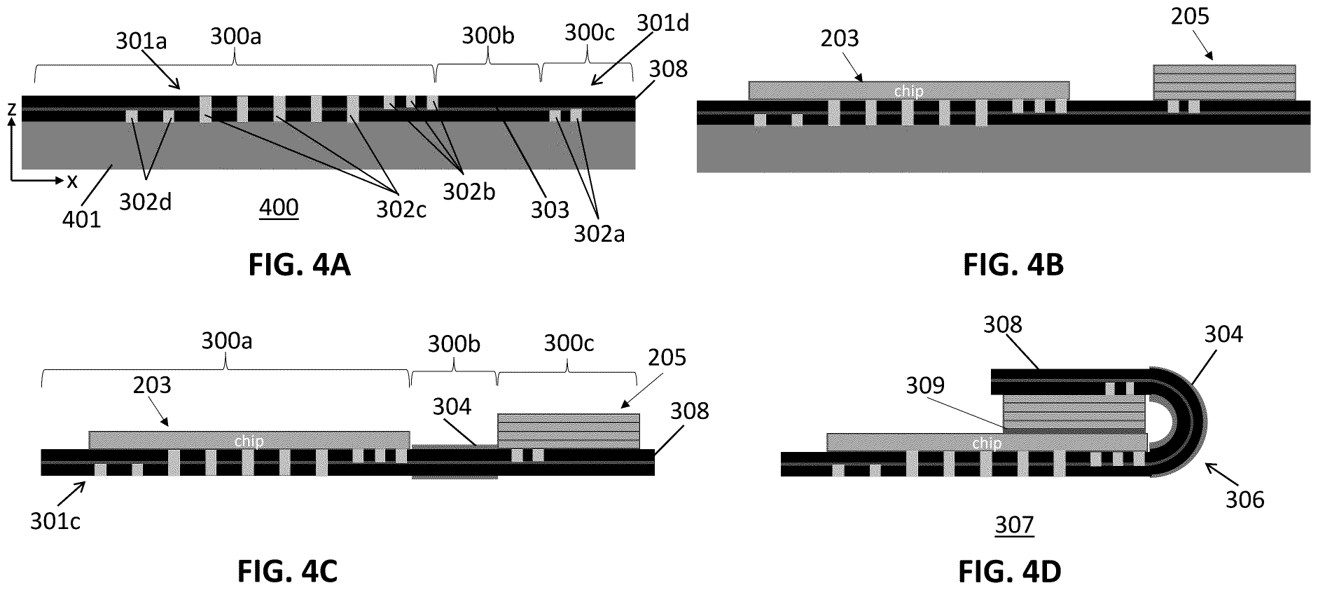

FIGS. 4A to 4D schematically illustrate selected steps of an example process for fabricating the bonded structure 307.

At a first fabrication step (FIG. 4A), an initial structure 400 comprising the flexible interposer 308 and a carrier layer or substrate 401 may be provided. In some examples, the base layer may comprise silicon, silicon dioxide, glass, polymer, epoxy, resin, polyimide, PBO, or other semiconductor or dielectric (organic or inorganic) materials. In some embodiments, the flexible interposer 308 may be bonded on a top surface of the carrier layer 401. In some implementations, the flexible interposer 308 may be formed or fabricated (e.g., grown, deposited) on the top surface of the carrier layer 401. For example, non-conductive layers, conductive lines, and contact pads of the flexible interposer 308 may be formed on the base layer using multiple fabrication steps comprising dielectric layer deposition, metallic layer deposition, patterning dielectric and metallic layers (e.g., lithographic patterning), polishing (e.g., chemical mechanical polishing), dielectric surface activation, and the like. In some implementations, the initial structure 400 may be configured such that the flexible interposer 308 is strained under the tensile stress inserted by the carrier layer 401. In some such implementations, a change of tensile strain in the flexible interposer 308 from the boundary of between the carrier layer 401 and the flexible interposer 308 to the top surface of the flexible interposer 308 may be configured such that in the absence the carrier layer 401 the flexible interposer 308 is naturally curved and its top surface becomes concave.

In some examples,, the first and second pluralities of contact pads 302a, 302b of the flexible interposer 308 may be extended from the top surfaces 301a, 301d of the first and second interposer portions 300a, 300c, respectively, to the conductive lines 303, the third and fourth pluralities of contact pads 302c, 302d may be extended from the top surface 301a and conductive lines 303, respectively, to the boundary formed between the flexible interposer 308 and the carrier layer 401.

In some implementations, fabrication of the flexible interposer 308 may comprise forming a deformable region in at least in the middle interposer portion 300b. In some examples, formation of the deformable region may comprise but not limited to deposition and, in some cases, patterning of a deformable layer (e.g., a polymer layer) and/or reducing a thickness of at least a region of the middle interposer portion 300b.

In some embodiments, the top surfaces 301a, 301d of the first and second interposer portions 300a and 300c of the flexible interposer 308 may be configured for TC bonding. In some embodiments, the top surfaces 301a, 301d, may be bonded using soldering (e.g., electrical and mechanical connections provided by an array of solder bumps).

In some embodiments, the top surfaces 301a, 301d of the first and second interposer portions 300a and 300c of the flexible interposer 308 may be configured for direct hybrid bonding. In some such embodiments, the flexible interposer 308 may comprise one or more features described above with respect to hybrid bonding structures 100, 102.

At a second fabrication step (FIG. 4B), the first device 203 is bonded on the top surface 301a of the first interposer portion 300a and the second device 205 is bonded on the top surface 301d of the second interposer portion 300c. In some implementations, the first and second devices 203, 205 can be hybrid bonded on the top surfaces 301a, 301d of the flexible interposer 308. In some implementations, the first and second devices 203, 205 can be TC bonded on the top surfaces 301a, 301d of the flexible interposer 308.

At a third fabrication step (FIG. 4C), the carrier layer 401 may be removed or separated from the flexible interposer 308 having the first and second devices 203, 205 bonded on its top surface. In some implementations, the carrier layer 401 may be removed by a polishing procedure, an etching procedure, or a combination thereof. Removal of the carrier layer 401 may expose conductive surfaces of some of the contact pads via a bottom surface of the flexible interposer 308. These exposed conductive surfaces may be used to electrically connect the flexible interposer 308 to a substrate, a board, or another interposer (e.g., a planar interposer). In some examples, after removing the carrier layer 401, the cladding layer 304 may be formed (e.g., deposited or coated) over one or both of top and bottom surfaces of the middle interposer portion 300b. In some examples, a composition and thickness of the cladding layer 304 may be selected based at least in part on a final radius of the middle interposer portion 300b (the radius of the bent portion 306) in the bonded structure 307.

At a fourth fabrication step (FIG. 4D), the second interposer portion 300c on which the second device 205 is bonded may be displaced (e.g., using an external force and torque) with respect to the first interposer portion 300a to bend the middle interposer portion 300b and to align the top surface of the second device 205 with the top surface of the first device 203 such that the top surface of the second device 205 with the top surface of the first device 203 become substantively parallel and nearly in contact. During operation of the bonded structure, the middle interposer portion 300b may remain bent or folded over.

In some embodiments, an adhesive layer 309 may be formed between the top surface of the second device 205 with the top surface of the first device 203 to mechanically couple the second device 205 to the first device 203 and maintain the final radius curvature of the middle interposer portion 300b (radius of curvature of the bent portion 306).

As described above, in some embodiments, before removing the carrier layer 401, the flexible interposer 308 can be under a tensile strain that changes (e.g., increases) along a direction normal to the main surface of the base layer toward the top surface of the flexible interposer 308. In these embodiments, removal of the base layer at step 3 may naturally result in bending and rolling of the flexible interposer 308 and formation of the bent portion 306. In some embodiments, when the flexible interposer naturally roles, the top surface of the second device 205 can become substantially aligned (e.g., becomes parallel to) with the top surface of the first device 203 by the natural rolling process. Advantageously, such self-rolling of the flexible interposer 308 may reduce or eliminate the need for the external control during the fourth fabrication step of the flexible interposer 308 for aligning top surface of the second device 205 with the top surface of the first device 203.

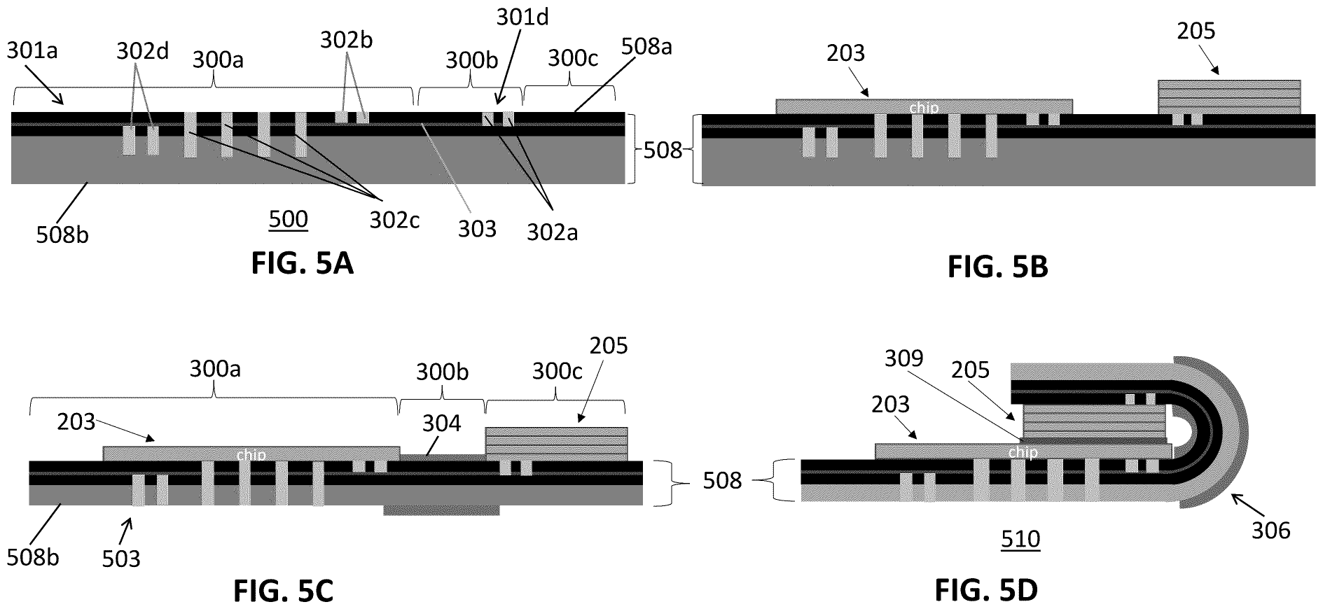

FIGS. 5A to 5D schematically illustrates selected steps of an example process for fabricating a bonded structure similar to bonded structure 307 based on a two-layer flexible interposer 508 having a top layer 508a and bottom layer 508b. In some embodiments, the top layer includes the conductive lines 303, which provides electrical connection between the contact pads of the flexible interposer 508. In some embodiments, the bottom layer 508b may provide mechanical support to the top layer 508a. In some embodiments, some of the contact pads or conductive vias of the flexible interposer 508 can be extended into a bottom surface 503 of the bottom layer 508b.

At a first fabrication step (FIG. 5A), an initial structure 500 comprising the top layer 508a and a thick bottom layer 508b (also referred to as support layer) may be provided.

In some examples, the top layer 508a can be a routing layer comprising a first non-conductive layer (e.g., a dielectric or semiconductor layer) having a plurality of horizontally extended conductive lines therein. In some examples, the thick bottom layer 508b may comprise a second non-conductive layer and a portion of contact pads formed therein. In some embodiments, the horizontally extended conductive lines of the initial structure 500 may be confined within or on the routing layer. In some examples, the first and second non-conductive layers may have different material compositions. In various implementations, the first and second non-conductive layers may comprise silicon, silicon dioxide, silicon nitride, silicon carbonitride, silicon oxynitride, and the like. In some embodiments, one or both of top layer 508a and the thick bottom layer 508b may comprise an organic material (e.g., a polymer, a resin, an epoxy, and the like). In some such embodiments, at least the top layer 508a may further comprise an inorganic bonding layer over the organic layer to serve as bonding layer. For example, a region of the middle interposer portion may comprise a polymer. In some embodiments, one or both top layer 508a and the thick bottom layer 508b may comprise two or more sublayers. In some examples, at least one of the sub-layers may comprise an organic material.

In some embodiments, the top layer 508a may be bonded on a top surface of the thick bottom layer 508b to form the initial structure 500. In some implementations, the top layer 508a may be fabricated (e.g., grown, deposited) on the top surface of the thick bottom layer 508b. For example, non-conductive layers, conductive lines, and contact pads of the flexible interposer 508 may be formed on the base layer using multiple fabrication steps comprising dielectric layer deposition, metallic layer deposition, patterning dielectric and metallic layers (e.g., lithographic patterning), polishing (e.g., chemical mechanical polishing), dielectric surface activation, and the like. In some implementations, the initial structure 500 may be configured such that the top layer 508a is strained under the tensile stress inserted by the thick bottom layer 508b. In some such implementations, a change of tensile strain in the flexible interposer 508 along a direction normal to the main surface of the flexible interposer 508 may be configured such that reduction of thickness of the thick bottom layer 508b results in natural rolling and formation of a bent or curved flexible interposer having a concave top surface.

In some examples, the first and second pluralities of contact pads 302a, 302b in the initial structure 500 may be extended from the top surfaces 301a, 301d of the first and second interposer portions 300a, 300c, respectively, to the conductive lines 303, the third and fourth pluralities of contact pads 302c, 302d may be extended from the top surface 301a and conductive lines 303, respectively, into the thick bottom layer 508b.

In some implementations, fabrication of one or both of the top layer 508a and the thick bottom layer 508b may comprise forming a deformable region in at least in the middle interposer portion 300b. In some examples, formation of the deformable region may comprise but not limited to deposition and, in some cases, patterning of a deformable layer (e.g., a polymer layer) and/or reducing a thickness of at least a region of the middle interposer portion 300b.

In some embodiments, the top surfaces 301a, 301d of the first and second interposer portions 300a and 300c may be configured for TC bonding.

In some embodiments, the top surfaces 301a, 301d of the first and second interposer portions 300a and 300c may be configured for direct hybrid bonding. In some such embodiments, one or both of the top layer 508a may comprise one or more features described above with respect to hybrid bonding structures 100, 102.

At a second fabrication step (FIG. 5B), the first device 203 is bonded on the top surface 301a of the first interposer portion 300a and the second device 205 is bonded on the top surface 301d of the second interposer portion 300c. In some implementations, the first and second devices 203, 205 can be hybrid bonded on the top surfaces 301a, 301d of the initial structure 500. In some implementations, the first and second devices 203, 205 can be TC bonded on the top surfaces 301a, 301d of the initial structure 500.

At a third fabrication step (FIG. 5C), thickness of the thick bottom layer 508b may be reduced to form the flexible interposer 508. In some implementations, the thickness of the thick bottom layer 508b may be reduced by a polishing procedure, an etching procedure, or a combination thereof. In some implementations, the thickness of the thick bottom layer 508b may be reduced to expose conductive surfaces of some of the contact pads and/or conductive vias through a resulting bottom surface 503 of the flexible interposer 508. These exposed conductive surfaces may be used to electrically connect the flexible interposer 508 to a substrate, a board, or another interposer (e.g., a planar interposer). In some examples, reducing the thickness of the thick bottom layer 508b and formation of the flexible interposer 508, the cladding layer 304 may be formed (e.g., deposited or coated) over one or both of top and bottom surfaces of the middle interposer portion 300b. In some examples, a composition and thickness of the cladding layer 304 may be selected based at least in part on a final radius of the middle interposer portion 300b (the radius of the bent portion 306) in the corresponding bonded structure.

At a fourth fabrication step (FIG. 5D), the second interposer portion 300c on which the second device 205 is bonded may be displaced (e.g., using an external force and torque) with respect to the first interposer portion 300a to bend the middle interposer portion 300b and to align the top surface of the second device 205 with the top surface of the first device 203 such that the top surface of the second device 205 with the top surface of the first device 203 become substantively parallel and nearly in contact.

In some embodiments, the thick bottom layer 508b (support layer) may be configured to mechanically support the initial structure 500 during formation of the initial structure 500 and bonding of devices on its top surface and the bottom layer 508b of the flexible interposer 508 may mechanically support the bent portion 306 after formation of the bonded structure 510.

In some embodiments, a thickness of the middle interposer portion 300b of the flexible interposers 308, 508, can be smaller than those of the first and second interposer portions 300a, 300c. In some examples, the thickness of the middle interposer portion 300b may be reduced prior to the second fabrication steps (shown in FIG. 4B or 5B) or prior to the fourth fabrication steps (shown in FIG. 4D or 5D).

As described above, in some embodiments, before reducing the thickness of the thick bottom layer 508b, the top layer 508a can be under a tensile strain that changes (e.g., increases) along a direction normal to the main surface of the initial structure 500 toward the top surface of the top layer 508a. In these embodiments, reducing the thickness of the thick bottom layer 508b at the fabrication step 3 (FIG. 5C) may naturally result in bending and rolling of the flexible interposer 508 and formation of the bent portion 306. In some embodiments, when the flexible interposer naturally roles, the top surface of the second device 205 can become substantially aligned (e.g., becomes parallel to) with the top surface of the first device 203 by the natural rolling process. Advantageously, such self-rolling of the flexible interposer 508 may reduce or eliminate the need for the external control during the fourth fabrication step (FIG. 5D) of the flexible interposer 508 for aligning top surface of the second device 205 with the top surface of the first device 203.

In some implementations, a gap between the top surfaces of the first and second devices 203, 205, formed after the alignment/bending process, may be filled with an adhesive (e.g., a low temperature adhesive) to form the adhesive layer 309 (e.g. die attach layer) mechanically connecting the that the top surface of the second device 205 to the top surface of the first device 203 and thereby forming bonded structure 510 shown in FIG. 5D.

With reference to the bonded structures shown in FIGS. 4D and 5D, in some examples, aligning the top surface of the second device 205 with the top surface of the first device 203 and bringing them into close contact may transform the middle interposer portion 300b to the bent portion 306 having a radius of curvature close to 50% of the combined thickness of the first and second devices 203, 205. In some examples, the adhesive layer 309 may be configured to maintain and stabilize the curvature of the bent portion 306.

With reference to the bonded structures shown in FIGS. 4D and 5D, In some embodiments, the top surface of the second device 205 may be bonded to the top surface of the first device 203 to mechanically couple the second device 205 to the first device 203 and maintain the final radius of curvature of the middle interposer portion 300b (e.g., the radius of curvature of the bent portion 306). For example, the top surface of the second device 205 and top surface of the first device 203 may comprise hybrid bonding surfaces and they may be hybrid bonded. In some embodiments, after formation of the bonded structure 307 or 510, at least a portion the boded structure 307 or 510 may be encapsulated in a dielectric (e.g., inorganic or organic) cladding configured to hold the components together during the operation.

In some embodiments, the second device 205 (e.g., a top surface of the second device 205) may be bonded on a top surface of the first device 203 using a direct dielectric-to-dielectric method. As explained herein non-conductive or dielectric-to-dielectric bonds may be formed without an adhesive using the direct bonding techniques.

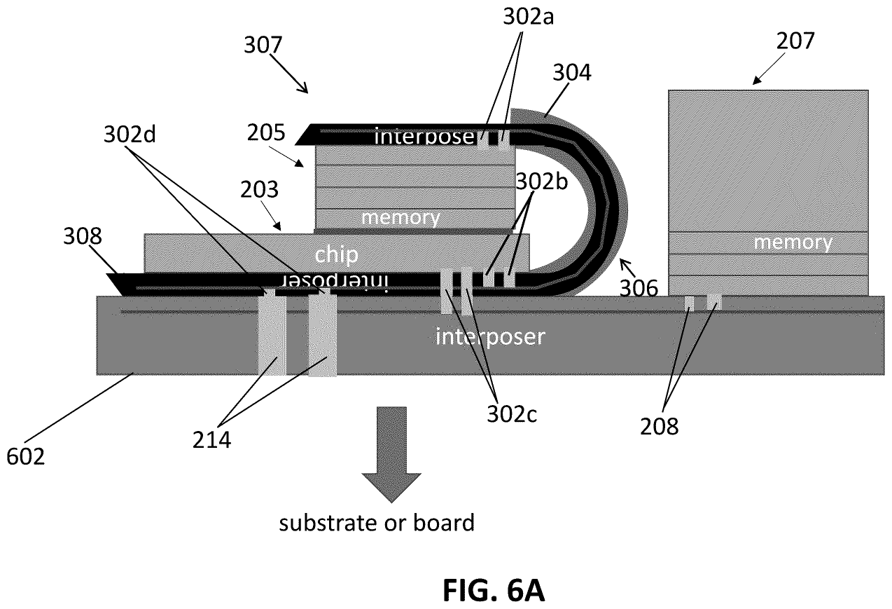

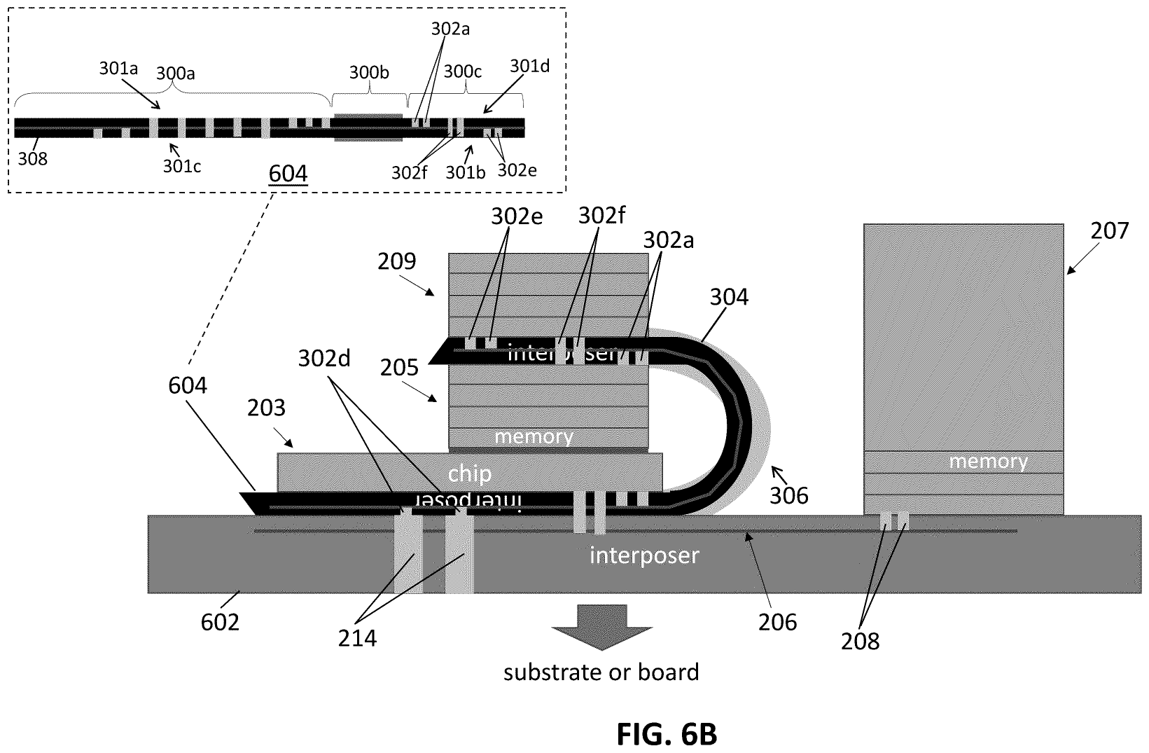

FIG. 6A schematically illustrates side-cross sectional view of an extended bonded structure comprising a planar interposer 602, the bonded structure 307 mounted or bonded on or over planar interposer 602, and a third device 207 (e.g., a memory device) mounted to the planar interposer 602 adjacent to the bonded structure 307. In some embodiments, the planar interposer 602 may comprise one or more features described above with respect to planar interposer 204. In some embodiments, instead of the planar interposer 602 the bonded structure 307 (or the bonded structure 510) and the third device 207 may be mounted or bonded on a substrate having there in an embedded bridge (e.g., the substrate 220 and the embedded interconnect region). In some embodiments, instead of the bonded structure 307, the bonded structure 510 may be mounted or bonded on the planar interposer 602 to be electrically connected to third device 207.

Advantageously, when electrical access to the first device 203 is not available through its top surface, the flexible interposer 300 may enable mounting the second device (e.g., the second memory device) over or on the first device 203 by electrically connecting the first device 203 to the planar interposer 602 (e.g., via its first interposer portion 300a) and to the second device 205 (e.g., via its middle and second interposer portions 300b, 300c). As such, using flexible interposer 300 may double amount of memory accessible by the first device 203 through additional electrical links provided by the flexible interposer 300, without occupying an additional region of the planar interposer 602. In some examples, the communication links established between the first and second devices 203, 205, via the bent portion 306 may have a bandwidth equal or greater than 10 GB/sec, equal or greater than 100 GB/sec, equal or greater than 500 GB/sec, equal or greater than 1000 GB/sec or greater values.

In some embodiments, the second interposer portion 300c of the flexible interposer 308 or 508 may comprise additional contact pads formed near a bottom surface of the second interposer portion 300c and electrically connected to the conductive lines 303.

In some embodiments, the second interposer portion 300c of the flexible interposer 308 or the flexible interposer 508 may comprise a fifth plurality of contact pads 302e configured to provide electrically connection to the flexible interposer (e.g., to the conductive lines 303 therein) via a bottom surface of the second interposer portion 300c opposite to the top surface 301d. In some such embodiments, the second interposer portion 300c may be electrically connected to two devices and thereby provide simultaneous electrical connection between a device electrically connected to the first, second, and/or third plurality of contact pads, and two devices electrically connected to the fourth and fifth plurality of contact pads (e.g., to top and bottom surfaces of the second interposer portion 300c). Additionally, in some implementations, the second interposer portion 300c of the flexible interposer 308 or the flexible interposer 508 may comprise a sixth plurality of contact pads 302f configured to provide electrical connection between a device bonded to the top surface 301d of the second interposer portion 300c and a device bonded to a bottom surface 301b (opposite to the top surface 301d) of the second interposer portion 300c. In some such embodiments, the second interposer portion 300c may electrically connect two devices and thereby provide simultaneous electrical connection between a device electrically connected to the first, second, and/or third plurality of contact pads, and two devices electrically connected to the fourth and fifth plurality of contact pads

FIG. 6B schematically illustrates an extended bonded structure comprising a flexible interposer 604 configured to electrically connect a first device 203 to second and fourth devices 203, 209 positioned above the first device, and a planar interposer 602 configured to electrically the flexible interposer 604, and thereby by the first device, to a third device 207. In some implementations, the first device may comprise a processor chip a the second, third, and fourth devices 205, 207, 209 may comprise memory devices. In some embodiments, the fourth device 209 may be positioned above the second device 203 and the third device 207 may be mounted (e.g., bonded) on and electrically connected to the planar interposer 602. The inset in FIG. 6B schematically illustrates the flexible interposer 604 (depicting corresponding interposer portions 300a, 300b, 300c and the contact pads therein) prior to bending and being included in the bonded structure. In some examples, the first interposer portion 300a of the flexible interposer 604 may be positioned between the planar interposer 602 and the first device 203 to be electrically connected to the first device 203 and to provide electrical connection between the second device 203 and the planar interposer 602. In some examples, the second interposer portion 300c of the flexible interposer 604 may be positioned between the second and fourth devices 203, 209 to be electrically connected to the second and fourth devices 203, 209, to electrically connect the second and fourth devices 203, 209 to the first device 203 (via the bent portion 306) and, in some cases, to provide electrical connection between the second and fourth devices 203, 209. In some examples, the flexible interposer 604 may electrically connect the second and fourth devices 203, 209 to the planar interposer 602 (via the bent portion 306).

Advantageously, when electrical access to the first device 203 is not available through its top surface, the flexible interposer 604 may enable mounting the second and fourth devices (e.g., memory devices) 205, 209 over or on the first device 203 by electrically connecting the first device 203 to the planar interposer 602 (e.g., via its first interposer portion 300a) and to the second and fourth devices 205, 209 (e.g., via its middle and second interposer sections 300b, 300c). As such, using flexible interposer 604 may triple the amount of memory accessible by the first device 203 through additional electrical links provided by the flexible interposer 604 without occupying an additional region of the planar interposer 602. In some examples, the communication links established between the first device 203, and second and fourth devices 203, 209, via the bent portion 306, may have a bandwidth equal or greater than 10 GB/sec, equal or greater than 100 GB/sec, equal or greater than 500 GB/sec, equal or greater than 1000 GB/sec or greater values.

In some embodiments, one or both the top surface 301d and bottom surface 301b of the second interposer portion 300c of the flexible interposer 604 may be configured for TC bonding. In these embodiments, one or both second device 205 and fourth device 209 may be TC bonded to the flexible interposer 604.

In some embodiments, one or both the top surface and bottom surface 301b of the second interposer portion 300c of the flexible interposer 604 may comprise a hybrid bonding surface configured for direct hybrid bonding and providing a direct bonding interface. In these embodiments, one or both second device 205 and fourth device 209 may be hybrid bonded to the flexible interposer 604.

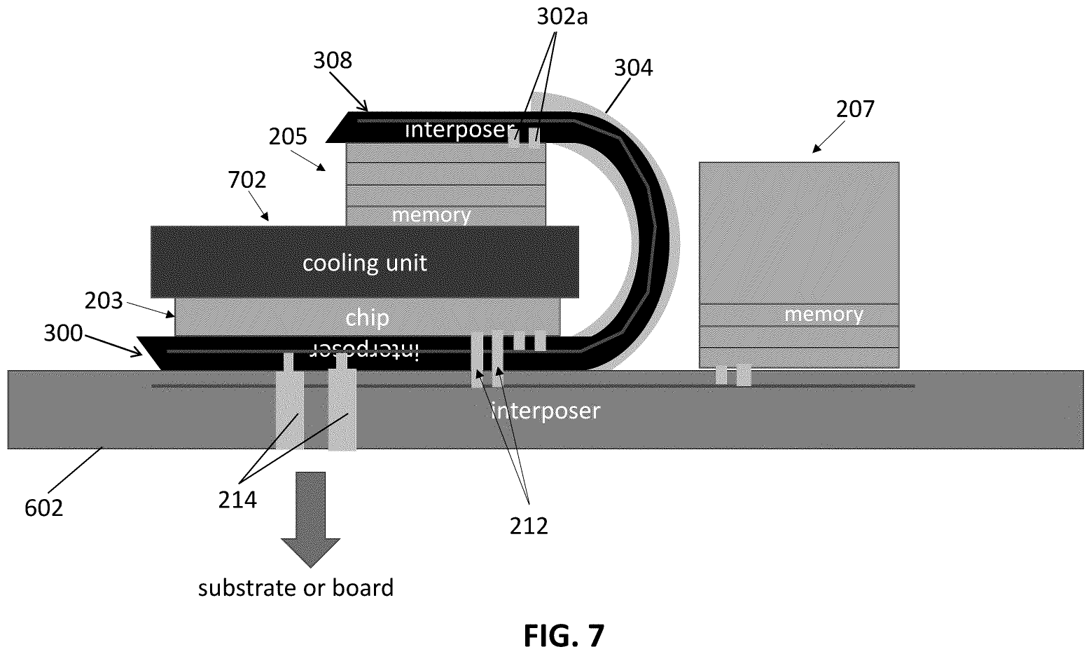

FIG. 7 schematically illustrates an extended bonded structure comprising a first device 203 electrically connected to a second device 205 device positioned above the first device 203 by a the flexible interposer 308 and to a third device 207 by the planar interposer 602. In some embodiments, the extended bonded structure shown in FIG. 7 may comprise one or more features described above with respect to extended bonded structure shown in FIG. 6A. In some embodiments, the second device 205 can be vertically separated from the first device 203 by a thermal control element 702 configured to control temperatures of the first and second devices 203, 205, e.g., by extracting thermal energy from these devices. In some examples, the thermal control element 702 may comprise a cooling device configured to absorb heat from the first and second devices 203, 205 (e.g., from the memory stack 205 and the processor chip 203) and dissipate the absorb heat to the surrounding medium of otherwise away from the bonded structure. In some cases, thermal control element 702 may have a top surface in thermal contact with the second device 205 (e.g., memory stack) and a bottom surface in thermal contact with the first device 203 (e.g., processor chip 203). In some examples, the thermal control element 702 may comprise cooling channels formed therein, through which a liquid can be conveyed to actively cool the first and second devices 203, 205. In some examples, the thermal control element 702 may comprise a thermoelectric cooling device (a thermoelectric cooler or TEC). Beneficially, as shown, the cooling device can be provided directly on the first device 203 (e.g., the processor chip), which can be the hottest part of the structure shown in FIG. 7. In some implementations, thermal contact may be provided by a thermal interface material to provide thermal conductance between surfaces of the first and second devices 203, 205. In some embodiments, one or both of the first and second devices 203, 205 can be bonded to the thermal control element 702 using a dielectric-to-dielectric bonding method. Examples of cooling devises for die stacks and method of bonding cooling devices to a die (e.g., a dielectric surface of a die) can be found throughout US 2023-0154828 and US 2024-0266255 the entire contents of each of which are incorporated by reference herein in their entirety and for all purposes.

It should be understood that although in the structures shown in FIGS. 6A, 6B, and 7, the processor chip is in electrical contact with one memory stack mounted above the processor chip and one memory stack disposed on the substrate, in various implementations, multiple memory stacks may be mounted above the processor chip and multiple memory stacks may be disposed on the substrate around the processor chip (e.g., at different lateral position) and be in electrical contact with the processor chip to establish a high bandwidth processor-memory connection. For example, one or more flexible interposers may be used to establish electrical connection between two or more memory stacks mounted above the processor chip and a substrate or another interposer on which the remaining memory stacks are mounted and electrically connected.

### Terminology

In various embodiments described above, thickness of a layer or sublayer may be defined with respect to a direction normal to an underlying surface on which the layer is formed.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
a processor chip disposed over a main surface of a first interposer;
a first memory device disposed over the first interposer; and
a second memory device disposed over the processor chip;
wherein the first memory device is electrically connected to the processor chip via the first interposer;
wherein the second memory device is electrically connected to the processor chip; and
wherein electrical connections between the processor chip and the first and second devices comprise a data communication link.

2.-4. (canceled)

5. The bonded structure of claim 1, wherein one or both the processor chip and the first memory device are hybrid bonded to the main surface of the first interposer via the hybrid bonding surface.

6. (canceled)

7. The bonded structure of claim 1, wherein at least one of the first and second memory devices comprise at least one high bandwidth memory die comprising a vertical stack of memory chips.

8.-10. (canceled)

11. The bonded structure of claim 1, wherein the first interposer comprises an embedded bridge device formed within a substrate.

12. (canceled)

13. The bonded structure of claim 1, wherein the second memory device is electrically connected to the processor chip via a second interposer comprising a bent interposer portion extending between the processor chip and the second memory device.

14. The bonded structure of claim 13, wherein the second interposer comprises a plurality of conductive lines configured to establish the data communication link.

15. The bonded structure of claim 13, wherein the second interposer comprises a first interposer portion between the first interposer and the processor chip, and a second interposer portion electrically connected to the second memory device, the first and second interposer portions being electrically connected by the bent interposer portion.

16. (canceled)

17. The bonded structure of claim 13, wherein the bent interposer portion comprise a deformable region.

18.-19. (canceled)

20. The bonded structure of claim 15, wherein the first interposer portion comprises at least one hybrid bonding surface directly hybrid bonded to the processor chip.

21. The bonded structure of claim 20, wherein the first interposer portion comprises a second hybrid bonding surface directly hybrid bonded to the first interposer.

22.-39. (canceled)

40. A bonded structure comprising:
a processor chip;
a first memory device disposed over the processor chip, and
a flexible interposer electrically connecting the processor chip to the first memory device;
wherein the flexible interposer comprises a first interposer portion electrically connected to the processor chip, a second interposer portion electrically connected to the first memory device, and a bent interposer portion electrically connecting the first and second interposer portions.

41.-44. (canceled)

45. The bonded structure of claim 40, wherein the bent interposer portion comprise a deformable region.

46. The bonded structure of claim 45, wherein Young's modulus of the deformable region is from 0.2 GPa to 45 GPa.

47. (canceled)

48. The bonded structure of claim 40, wherein the first interposer portion comprises a hybrid bonding surface directly hybrid bonded to the processor chip.

49. The bonded structure of claim 40, wherein the first interposer portion is bonded to the processor chip by thermocompression bonding.

50. The bonded structure of claim 40, wherein the second interposer portion comprises a first hybrid bonding surface directly hybrid bonded to the first memory device.

51. The bonded structure of claim 50, wherein the second interposer portion further comprises a second hybrid bonding surface opposite to the first hybrid bonding surface, and wherein the second hybrid bonding surface is hybrid bonded to a second memory device.

52.-55. (canceled)

56. The bonded structure of claim 51, wherein the second memory device is electrically connected to the processor chip by the flexible interposer.

57.-59. (canceled)

60. The bonded structure of claim 40, wherein the flexible interposer electrically connects the processor chip to the first memory device to establish a data communication link.

61. (canceled)

62. The bonded structure of claim 60, wherein the data communication link comprises a 1024-bit wide communication channel.

63.-82. (canceled)
